(19) United States
(12) Patent Application Publication
(10) Pub. No.: US 2026/0026371 A1
(43) Pub. Date: Jan. 22, 2026

(54) CIRCUIT BOARD AND SEMICONDUCTOR PACKAGE COMPRISING SAME

(71) Applicant: LG INNOTEK CO., LTD., Seoul (KR)

(72) Inventors: Nam Heon KIM, Seoul (KR); Na Kyung KWON, Seoul (KR); Ji Myoung LEE, Seoul (KR); Won Suk JUNG, Seoul (KR)

(73) Assignee: LG INNOTEK CO., LTD., Seoul (KR)

(21) Appl. No.: 19/111,833

(22) PCT Filed: Sep. 18, 2023
(86) PCT No.: PCT/KR2023/014085

§ 371 Date: Mar. 14, 2025

(30) Foreign Application Priority Data
Sep. 16, 2022 (KR) 10-2022-0117077
Sep. 16, 2022 (KR) 10-2022-0117080

(51) Int. Cl. H01L 23/538

(52) U.S. Cl. CPC H01L 23/538

(57) ABSTRACT

A circuit board according to an embodiment includes an insulating layer; a pad part disposed on the insulating layer; a conductive metal part disposed on the pad part; a protective layer disposed on the conductive metal part; and a bonding part passing through at least a part of the protective layer and electrically connected to the conductive metal part, wherein the pad part includes a first portion inclined to widen a width in a horizontal direction along a vertical direction from an upper surface of the pad part toward a lower surface of the insulating layer, and a second portion extending from the first portion and having an inclination different from an inclination of the first portion, and the conductive metal part is disposed to cover at least a part of a side surface of the first portion.

### TECHNICAL FIELD

An embodiment relates to a semiconductor package, and in particular, to a circuit board including a bonding part having a uniform height and a semiconductor package including the same.

### BACKGROUND ART

A performance of electric/electronic products is increasing, and accordingly, technologies for arranging a larger number of semiconductor devices on a semiconductor package substrate of a limited size are being proposed and studied. However, since a general semiconductor package is based on mounting a single semiconductor device, there is a limit to obtaining a desired performance.

Accordingly, a recent semiconductor package is arranging a plurality of semiconductor devices using a plurality of circuit boards. The semiconductor package has a structure in which a plurality of semiconductor devices are connected to each other in a horizontal direction and/or vertical direction on the circuit board. Accordingly, the semiconductor package has the advantage of efficiently using a mounting area of the semiconductor device and transmitting high-speed signals through a short signal transmission path between the semiconductor devices.

In addition, a number of semiconductor devices and/or a size of each semiconductor device increases, or a functional part of the semiconductor device is divided according to a trend of high integration, and a concept of a semiconductor package applied to products that provide an internet of things (IoT), an autonomous vehicle, and a high-performance server, etc. is expanding into semiconductor chiplets.

Accordingly, an intercommunication between semiconductor devices and/or semiconductor chiplets is becoming important, and accordingly, there is a trend to mount an interposer between a semiconductor package substrate connected to a main board of an electronic device and the semiconductor device.

An interposer can function as a redistribution layer that gradually increases a width or length of a circuit pattern from the semiconductor device to the semiconductor package in order to facilitate the intercommunication between the semiconductor device and/or semiconductor chiplets, or to interconnect the semiconductor device and the semiconductor package substrate. Accordingly, it can function to facilitate an electrical signal between the semiconductor device and the semiconductor package substrate having a relatively large circuit pattern compared to the circuit pattern of the semiconductor device.

Meanwhile, recently, as functions provided by semiconductor devices increase and the performance of semiconductor devices improves, a number of I/O terminals provided in the semiconductor device is also increasing. Accordingly, as a width and/or pitch of the I/O terminals provided in the semiconductor device become smaller, an electrical short circuit may occur in which a plurality of coupling members come into contact with each other in a process of connecting the I/O terminals of the semiconductor device through coupling members such as solder. Accordingly, as a density of terminals of semiconductor devices increases, a micro bonding process such as thermal compression bonding (hereinafter referred to as ‘TC bonding’) can be performed to reduce an amount of the coupling member such as solder. In addition, if a micro bonding process is performed, the interposer and/or the semiconductor package substrate can be provided with a bonding part to improve alignment with terminals of the semiconductor device. The semiconductor package substrate can have a bonding part protruding on the interposer and/or the semiconductor package substrate, thereby reducing a volume of the coupling member and increasing alignment with the terminals of the semiconductor device.

At this time, due to process deviation in a plating process for forming the bonding part and/or differences in width in a horizontal direction and/or area of a lower surface of each of the plurality of bonding parts, a difference in a current applied during the plating process occurs, and this can cause a difference in a plating process speed. Therefore, a height deviation can occur between the plurality of bonding parts. If there is a height deviation between a plurality of bonding parts, the semiconductor device may not be mounted stably, and electrical connection reliability between the semiconductor device and the circuit board may deteriorate.

### DISCLOSURE

### Technical Problem

The embodiment provides a circuit board with improved adhesion between an insulating layer and an electrode part and a semiconductor package including the same.

In addition, the embodiment provides a circuit board and a semiconductor package having a uniform centerline average surface roughness (Ra) applied to an interface between an insulating layer and an electrode part.

In addition, the embodiment provides a circuit board with improved electrical reliability and a semiconductor package including the same.

In addition, the embodiment provides a circuit board in which a chemical copper plating layer of an electrode part and a reinforcing member in an insulating layer do not come into contact with each other and a semiconductor package including the same.

In addition, the embodiment provides a circuit board in which a height deviation between a plurality of bonding parts is minimized and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer; a pad part disposed on the insulating layer; a conductive metal part disposed on the pad part; a protective layer disposed on the conductive metal part; and a bonding part passing through at least a part of the protective layer and electrically connected to the conductive metal part, wherein the pad part includes a first portion inclined to widen a width in a horizontal direction along a vertical direction from an upper surface of the pad part toward a lower surface of the insulating layer, and a second portion extending from the first portion and having an inclination different from an inclination of the first portion, and the conductive metal part is disposed to cover at least a part of a side surface of the first portion.

In addition, the bonding part includes a protruding portion disposed on the protective layer, and a through portion extended from the protruding portion and passing through at least a part of the protective layer and electrically connected to the conductive metal part.

In addition, the insulating layer has a reinforcing member, and at least a part of the side surface of the first portion of the pad part does not overlap with the reinforcing member of the insulating layer in the horizontal direction.

In addition, a recess is provided at an upper surface of the insulating layer, and the first portion of the pad part is disposed in the recess.

In addition, the conductive metal part includes a metal material different from a metal material of at least one of the pad part and the bonding part.

In addition, the side surface of the first portion of the pad part has a curved surface.

In addition, the through portion does not overlap with the curved surface in the vertical direction.

In addition, a width of the protruding portion in the horizontal direction is smaller than a width of the second portion of the pad part.

In addition, the conductive metal part includes a contact portion in contact with an upper surface of the first portion of the pad part, and an extension portion extending from the contact portion and not overlapping the upper surface of the first portion along the vertical direction.

In addition, the extension portion overlaps the curved surface along a vertical direction.

In addition, the extension portion is bent toward the upper surface of the insulating layer from the contact portion and overlaps the side surface of the first portion of the pad part in the horizontal direction.

In addition, the extension portion includes an upper surface, an inner surface facing the side surface of the first portion of the pad part, an outer surface opposite the inner surface, and a lower surface between the inner surface and the outer surface, and the upper surface and the outer surface of the extension portion are in contact with the protective layer.

In addition, the lower surface of the extension portion does not contact the side surface of the first portion of the pad part.

In addition, the lower surface of the extension portion is in contact with the protective layer.

In addition, the inner surface of the extension portion is in contact with the side surface of the first portion of the pad part.

In addition, at least a part of the inner surface of the extension portion does not contact the side surface of the first portion of the pad part and contacts the protective layer.

In addition, the extension portion does not overlap with the side surface of the first portion of the pad part along a horizontal direction.

In addition, the lower surface of the extension portion is in contact with the side surface of the first portion of the pad part.

In addition, a width of the through portion is smaller than a width of the conductive metal part in the horizontal direction.

In addition, a width of the through portion is smaller than a width of the upper surface of the first portion of the pad part.

In addition, a vertical length of the through portion is larger than a vertical length of the pad part.

In addition, a vertical length of the through portion is smaller than a vertical length of the pad part.

In addition, the circuit board further includes a connection circuit pattern part that overlaps the second portion of the pad part in a horizontal direction and does not overlap the pad part in a vertical direction, and the connection circuit pattern part does not overlap the second portion of the pad part in a horizontal direction.

In addition, the insulating layer includes a first layer including a reinforcing member; and a second layer provided on the first layer and not including a reinforcing member, and at least a part of the pad part overlaps the second layer in a horizontal direction.

In addition, a recess is provided at the upper surface of the insulating layer, and each of the first portion and the second portion of the pad part is disposed in the recess.

In addition, the conductive metal part includes a first region disposed on the pad part, and a second region extending from the first region between the side surface of the first portion of the pad part and an inner wall of the recess.

In addition, the second region of the conductive metal part overlaps with at least a part of each of the first layer, the second layer, and the pad part in a horizontal direction.

In addition, the recess includes a first part provided in the first layer of the insulating layer; and a second part provided in the second layer of the insulating layer and connected to the first part.

In addition, the upper surface of the pad part is positioned lower than an upper surface of the second layer of the insulating layer.

In addition, the side surface of the first portion of the pad part overlaps with the recess and the inner wall in a horizontal direction, and is spaced apart from the inner wall of the recess.

In addition, the side surface of the second portion of the pad part is in contact with the inner wall of the recess.

In addition, the conductive metal part is provided between the side surface of the first portion of the pad part and the inner wall of the recess.

In addition, the conductive metal part includes a portion protruding onto the second layer of the insulating layer, and at least a part of the protruding portion of the conductive metal part is in contact with an upper surface of the second layer of the insulating layer.

In addition, the reinforcing member is a filler provided in a resin of an organic material, and the second layer of the insulating layer is a pure resin layer that does not include a filler.

In addition, a first surface roughness is provided at the upper surface of the second layer of the insulating layer, and a second surface roughness different from the first surface roughness is provided at an interface between the first layer and the second layer of the insulating layer.

In addition, a second surface roughness corresponding to a particle size of the filler provided in the first layer of the insulating layer is provided at an interface.

In addition, the first surface roughness is a centerline average surface roughness (Ra) in a range of 0.2 μm to 1.5 μm.

In addition, the inner wall of the recess has a third surface roughness smaller than the first surface roughness.

In addition, a deviation of the centerline average surface roughness of a plurality of lines provided at the upper surface of the second layer of the insulating layer is smaller than a deviation of the centerline average surface roughness of a plurality of lines provided at the interface between the first layer and the second layer.

In addition, the first layer of the insulating layer is provided with fillers having different particle sizes, and a value of the centerline average surface roughness at the upper surface of the second layer is smaller than an average value of particle sizes of the fillers.

### Advantageous Effects

The circuit board of the embodiment can minimize a height deviation between a plurality of bonding parts connected to coupling members. Specifically, the circuit board of the embodiment can include a pad part. The pad part can include a first portion embedded in an insulating layer and a second portion provided on the first portion and protruding on the insulating layer. In addition, the circuit board can include a connection circuit pattern part corresponding to a trace that overlaps the first portion of the plurality of pad parts in a horizontal direction. At this time, the second portion of the pad part can be a seed layer for forming the first portion of the pad part and the connection circuit pattern part by electrolytic plating.

Specifically, a conventional circuit board completely removes a copper layer used as the seed layer. Accordingly, a thickness of the bonding part provided on the pad part in the conventional circuit board can increase. As a result, the conventional circuit board can have a height deviation between the plurality of bonding parts that are spaced apart from each other in a horizontal direction. Accordingly, when bonding a semiconductor device onto a bonding part, the conventional circuit board may not stably place the semiconductor device on the bonding part due to a height difference between the plurality of bonding parts and may be bonded in a state of being tilted in a specific direction. In contrast, the embodiment may not remove a part of a region of a copper layer used as a seed layer where the bonding part is to be disposed, thereby allowing the pad part to have a second portion, which is a part of the copper layer that has not been removed as described above. At this time, an upper surface of the second portion of the pad part may mean an upper surface of a copper layer that is preferentially disposed on a carrier member during a manufacturing process of the circuit board. Accordingly, an upper surface of the second portion of the pad part may be flat. Furthermore, upper surfaces of the second portions of the plurality of pad parts may be positioned on a same plane. Therefore, the embodiment may form a plurality of bonding parts with a uniform thickness and/or height by arranging a bonding part on the second portion of the pad part. Furthermore, the embodiment may reduce a thickness of the bonding part by a thickness of the second portion of the pad part. Accordingly, the embodiment can solve a problem that a thickness deviation between the plurality of bonding parts increases in proportion to a thickness of the bonding part. Accordingly, the embodiment can minimize the height deviation between the plurality of bonding parts. Therefore, the embodiment can stably dispose the semiconductor device on the plurality of bonding parts. Furthermore, the embodiment can increase a thickness of the bonding part by a thickness of the second portion of the pad part compared to a thickness of a conventional bonding part. Furthermore, the embodiment can minimize a thickness deviation between the plurality of bonding parts by forming the bonding part using a pad part having a uniform height even if the thickness of the bonding part is increased.

Accordingly, the embodiment can secure a height of the bonding part at which the semiconductor device can be stably bonded, and can improve overall physical characteristics and/or electrical characteristics of the semiconductor package. Accordingly, the semiconductor device can be operated smoothly, and further, a server or an electronic product can be operated smoothly.

In addition, the bonding part may include a through portion passing through at least a portion of a region of the protective layer from an upper surface of the protective layer, and a bonding portion disposed on the through portion and protruding onto the protective layer. The second portion of the pad part may include a side surface having a curvature. The through portion of the bonding part may overlap the side surface having the curvature of the pad part in a vertical direction. Therefore, when forming the through portion of the bonding part, the embodiment may allow the through-portion to be biased to one side on the pad part. Through this, the embodiment may increase a spacing between a plurality of through portions adjacent to each other, and further, between a plurality of bonding parts adjacent to each other. The embodiment may increase an amount of coupling members disposed on the bonding part by increasing the spacing between the bonding parts, thereby improving a bonding strength between the semiconductor device and the circuit board.

In addition, a conductive metal part of the bonding part may include a contact portion overlapping an upper surface of the pad part in a vertical direction, and an extension portion overlapping a side surface of the pad part having the curvature in a vertical direction. The extension portion may be bent in a bending direction corresponding to the curvature of the side surface of the pad part from the contact portion. Through this, the embodiment may increase a contact area between the protective layer and the pad part by using the extension portion, thereby improving the bonding force between the protective layer and the pad part.

In addition, at least a part of an inner surface of the extension portion of the conductive metal part may not be in contact with the side surface of the pad part. Through this, a certain separation space may be provided between the side surface of the pad part and the inner surface of the extension portion. At this time, the protective layer may be provided to fill the separation space. At this time, the separation space may function as an anchor that improves the bonding force with the protective layer. Through this, the embodiment may improve an adhesion between the insulating layer and the protective layer and an adhesion between the protective layer and the bonding part.

An insulating layer of another embodiment may include a first layer including a reinforcing member and a second layer on the first layer. The first layer of the insulating layer may include a reinforcing member such as a filler, and the second layer may not include a reinforcing member and may be, for example, a pure resin layer. Through this, the embodiment can improve electrical characteristics of an electrode part while securing the adhesion between the insulating layer and the circuit layer. Specifically, the insulating layer of a comparative example includes only the first layer equipped with the reinforcing member as a whole, and accordingly, a problem occurs in which the reinforcing member equipped in the first layer is in contact with the circuit layer. When the circuit layer is in contact with the filler, a decrease in adhesion occurs in a corresponding contact region, and a transmission loss of a signal transmitted through the circuit layer increases due to physical properties of the reinforcing member, which may deteriorate the electrical characteristics. In addition, when a content of the reinforcing member equipped in the insulating layer is reduced to solve the problem, a rigidity of the circuit board may be deteriorated. When the rigidity of the circuit board is deteriorated, a reliability problem in which the circuit board is greatly bent in a specific direction may occur.

Therefore, the embodiment allows the insulating layer to be divided into the first layer and the second layer, thereby securing the adhesion between the electrode part and the insulating layer while improving electrical characteristics of the electrode part. To this end, the first layer of the insulating layer may be composed of an organic material including the reinforcing member. Through this, the first layer can secure the rigidity of the insulating layer while allowing the electrode part to be stably disposed on the insulating layer. The second layer of the insulating layer can be provided on the first layer of the insulating layer. The second layer of the insulating layer may not include a reinforcing member, and the electrode part can be disposed on the second layer of the insulating layer. For example, the electrode part can be in contact with the second layer of the insulating layer. At this time, the second layer of the insulating layer may not be provided with a reinforcing member, and thus, the electrode part may not be in contact with the reinforcing member. Therefore, the embodiment can improve the adhesion between the electrode part and the insulating layer. Furthermore, the embodiment can improve electrical characteristics of the electrode part.

In addition, the electrode part of the embodiment can include a lower wiring electrode, and the lower wiring electrode can include a first metal layer of a chemical copper plating layer. At this time, the insulating layer includes a third layer below the first layer, and the third layer of the insulating layer may not include a reinforcing member. In addition, a centerline average surface roughness (Ra) of a certain level can be provided at a lower surface of the third layer. Accordingly, the embodiment can improve the adhesion between the first metal layer of the lower wiring electrode and the insulating layer. At this time, the first metal layer of the embodiment does not contact the first layer of the insulating layer. That is, the first metal layer does not contact the reinforcing member provided in the first layer of the insulating layer. Through this, the embodiment can solve the problem of the adhesion between the first metal layer and the insulating layer being reduced by the reinforcing member. Furthermore, the embodiment can prevent the transmission loss of the signal transmitting through the first metal layer from increasing by the reinforcing member. Through this, the embodiment can improve the physical reliability and electrical reliability of the circuit board.

In addition, the embodiment may impart a uniform surface roughness to the upper surface of the second layer by allowing the insulating layer to include the first layer and the second layer. Through this, the embodiment can provide a conductive metal part and/or a bonding part with a uniform thickness. Specifically, the embodiment may allow the conductive metal part and/or the bonding part spaced apart from each other in the horizontal direction to have a uniform thickness by arranging the conductive metal part and/or the bonding part on the second layer of the insulating layer to which uniform surface roughness is applied. Through this, the embodiment can allow a semiconductor device to be stably bonded to the conductive metal part and/or the bonding part. Therefore, the embodiment can improve operating characteristics of the semiconductor device and a product including the same.

### DESCRIPTION OF DRAWINGS

FIG. 1a is a cross-sectional view showing a semiconductor package according to a first embodiment.

FIG. 1b is a cross-sectional view showing a semiconductor package according to a second embodiment.

FIG. 1c is a cross-sectional view showing a semiconductor package according to a third embodiment.

FIG. 1d is a cross-sectional view showing a semiconductor package according to a fourth embodiment.

FIG. 1e is a cross-sectional view showing a semiconductor package according to a fifth embodiment.

FIG. 1f is a cross-sectional view showing a semiconductor package according to a sixth embodiment.

FIG. 1g is a cross-sectional view showing a semiconductor package according to a seventh embodiment.

FIG. 2 is a cross-sectional view showing a circuit board according to a first embodiment.

FIG. 3 is a plan view of a first electrode provided at an uppermost side of a first insulating layer of FIG. 2.

FIG. 4 and FIG. 5 are enlarged views showing a part of a region of the circuit board provided in FIG. 2.

FIG. 6 is an enlarged view showing a first modified example of the circuit board of FIG. 2.

FIG. 7 is an enlarged view showing a second modified example of the circuit board of FIG. 2.

FIG. 8 is an enlarged view showing a third modified example of the circuit board of FIG. 2.

FIG. 9 is an enlarged view showing a fourth modified example of the circuit board of FIG. 2.

FIG. 10 is an enlarged view showing a fifth modified example of the circuit board of FIG. 2.

FIG. 11 is an enlarged view showing a sixth modified example of the circuit board of FIG. 2.

FIGS. 12 to 23 are cross-sectional views showing a manufacturing method of the circuit board shown in FIG. 2 in order of processes.

FIG. 24 is a cross-sectional view showing a circuit board according to a second embodiment.

FIG. 25 is an optical microscope photograph showing an interface of an insulating layer provided in a circuit board according to the embodiment of FIG. 24.

FIG. 26 is a cross-sectional view showing a state before arranging a conductive metal part in a region of FIG. 24.

FIG. 27 is a drawing showing a state after arranging a conductive metal part in FIG. 26.

FIG. 28 is a drawing showing a detailed layer structure of a lower wiring electrode in the circuit board of FIG. 24.

FIG. 29 is a cross-sectional view showing a circuit board according to a third embodiment.

FIG. 30 is a cross-sectional view showing a circuit board according to a fourth embodiment.

FIG. 31 is a cross-sectional view showing a circuit board according to a fifth embodiment.

### BEST MODE

Hereinafter, embodiments of the present disclosure will be described in detail with reference to the accompanying drawings.

However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present disclosure, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements. Further, when expressed as “on (over)” or “under (below)”, it may include not only the upper direction but also the lower direction based on one element.

### —Electronic Device—

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor chip. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, a computer, a monitor, a tablet, a laptop, a netbook, a television, a video game, a smart watch, an automotive, or the like. However, the embodiment is not limited thereto, and may be any other electronic device that processes data in addition to these.

Hereinafter, a semiconductor package including a circuit board according to an embodiment will be described. The semiconductor package of the embodiment may have various package structures including a circuit board to be described later.

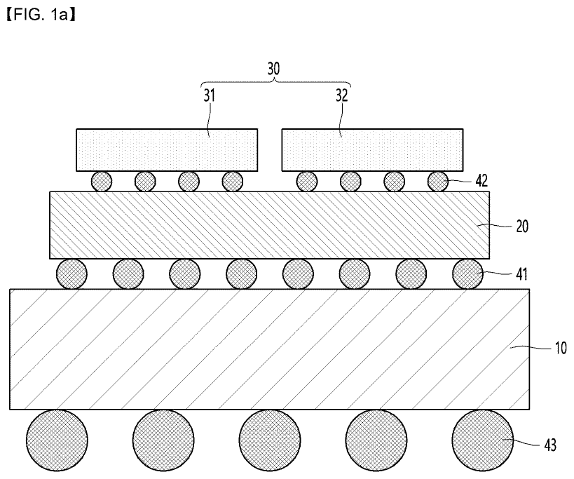

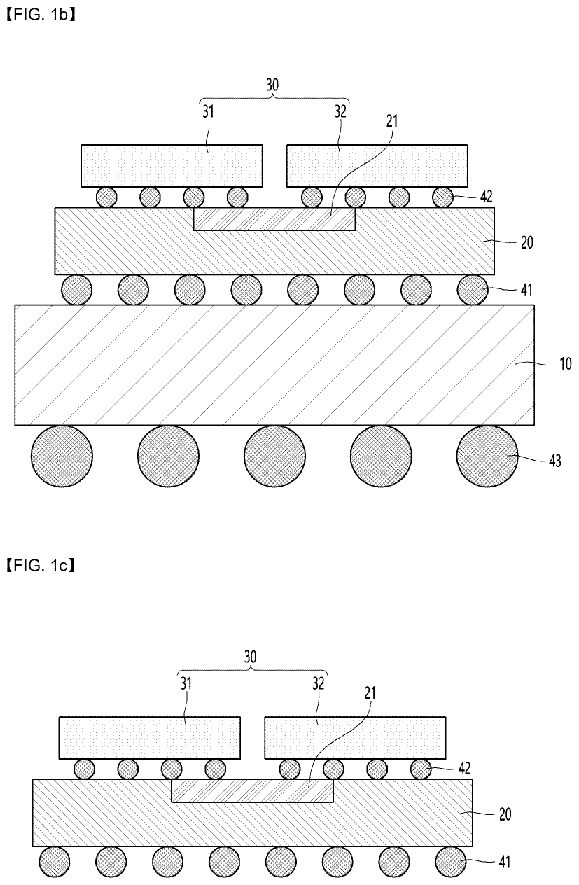

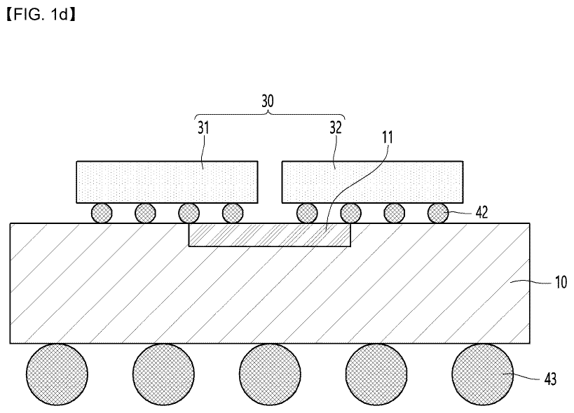

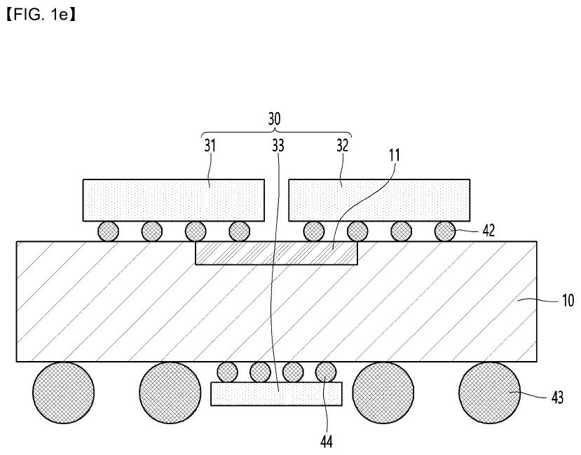

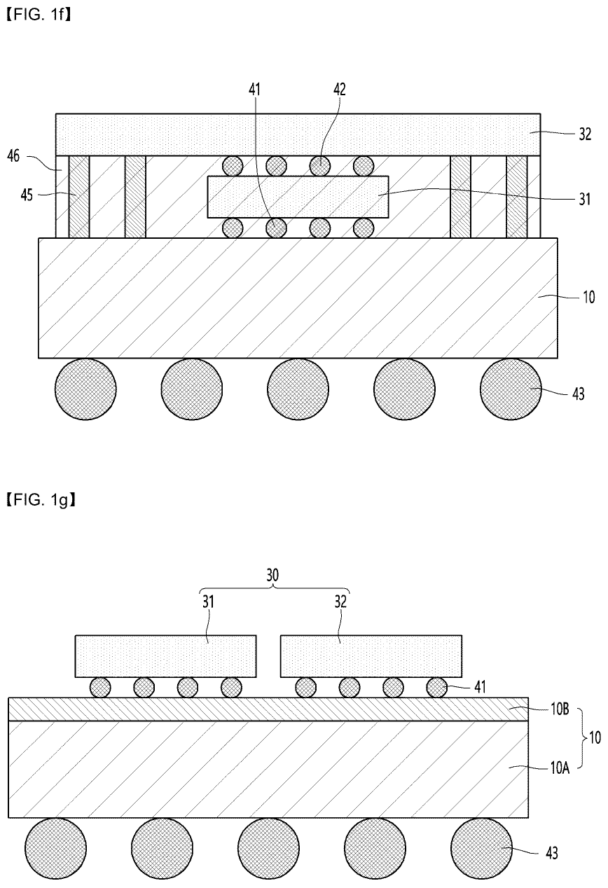

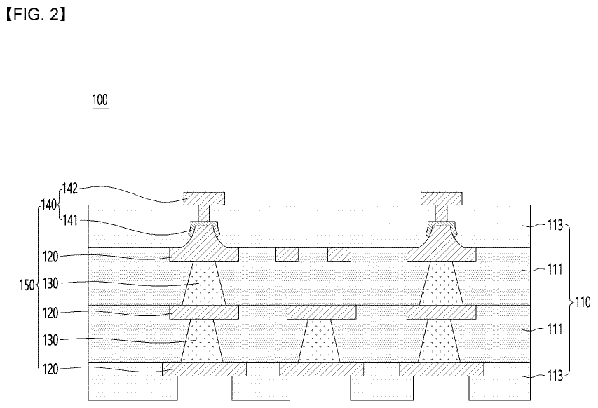

FIG. 1a is a cross-sectional view showing a semiconductor package according to a first embodiment, FIG. 1b is a cross-sectional view showing a semiconductor package according to a second embodiment, FIG. 1c is a cross-sectional view showing a semiconductor package according to a third embodiment, FIG. 1d is a cross-sectional view showing a semiconductor package according to a fourth embodiment, FIG. 1e is a cross-sectional view showing a semiconductor package according to a fifth embodiment, FIG. 1f is a cross-sectional view showing a semiconductor package according to a sixth embodiment, and FIG. 1g is a cross-sectional view showing a semiconductor package according to a seventh embodiment.

Referring to FIG. 1a, the semiconductor package according to the first embodiment may include a first circuit board 10, a second circuit board 20, and a semiconductor device 30.

The first circuit board 10 means a semiconductor package substrate.

For example, the first circuit board 10 may provide a space to which at least one external circuit board is coupled. The external circuit board may refer to a second circuit board 20 coupled to the first circuit board 10. Also, the external circuit board may refer to a main board included in an electronic device coupled to a lower portion of the first circuit board 10.

Also, although not shown in the drawing, the first circuit board 10 may provide a space in which at least one semiconductor device is mounted.

The first circuit board 10 includes at least one insulating layer, a circuit pattern layer disposed on the at least one insulating layer, and a through electrode passing through the at least one insulating layer.

A second circuit board 20 is disposed on the first circuit board 10.

The second circuit board 20 may be an interposer. For example, the second circuit board 20 may provide a space in which at least one semiconductor device is mounted. The second circuit board 20 may be connected to the at least one semiconductor device 30. For example, the second circuit board 20 may provide a space in which the first semiconductor device 31 and the second semiconductor device 32 are mounted. The second circuit board 20 may electrically connect the first and second semiconductor devices 31 and 32 and the first circuit board 10 while electrically connecting the first semiconductor device 31 and the second semiconductor device 32. That is, the second circuit board 20 may perform a horizontal connection function between a plurality of semiconductor devices and a vertical connection function between the semiconductor devices and a package circuit substrate.

FIG. 1a illustrates that the first and second semiconductor devices 31 and 32 are disposed on the second circuit board 20, but is not limited thereto. For example, one semiconductor device may be disposed on the second circuit board 20, or alternatively, three or more semiconductor devices may be disposed.

The second circuit board 20 may be disposed between at least one semiconductor device 30 and the first circuit board 10.

In an embodiment, the second circuit board 20 may be an active interposer that functions as a semiconductor device. When the second circuit board 20 functions as a semiconductor device, the semiconductor package of the embodiment may have a structure that is vertically stacked on the first circuit board 10 and may have functions of multiple logic chips. Having the function of a logic chip may mean that it may have functions of an active device and a passive device. In a case of an active device, characteristics of current and voltage may not be linear unlike a passive device, and in a case of an active interposer, it may have the function of an active device. In addition, the active interposer may perform a function of a corresponding logic chip while performing a signal transmission function between a second logic chip disposed thereon and the first circuit board 10.

According to another embodiment, the second circuit board 20 may be a passive interposer. For example, the second circuit board 20 may function as a signal relay between the semiconductor device 30 and the first circuit board 10, and can have a passive device function such as a resistor, capacitor, or inductor. For example, a number of terminals of the semiconductor device 30 is gradually increasing due to 5G, Internet of Things (IoT), increased image quality, and increased communication speed. That is, the number of terminals provided in the semiconductor device 30 increases, thereby reducing the width of the terminals or an interval between the plurality of terminals. In this case, the first circuit board 10 is connected to the main board of the electronic device. There is a problem in that the thickness of the first circuit board 10 increases or the layer structure of the first circuit board 10 becomes complicated in order for the electrodes provided on the first circuit board 10 to have a width and an interval to be respectively connected to the semiconductor device 30 and the main board. Accordingly, in the first embodiment, the second circuit board 20 is disposed on the first circuit board 10 and the semiconductor device 30. In addition, the second circuit board 20 may include electrodes having a fine width and a spacing corresponding to the terminals of the semiconductor device 30.

The semiconductor package includes a first coupling member 41 positioned between a first circuit board 10 and a second circuit board 20. The first coupling member 41 electrically connects the first circuit board 10 and the second circuit board 20 while bonding the second circuit board 20 to the first circuit board 10.

The semiconductor package may include a second coupling member 42 disposed between the second circuit board 20 and the semiconductor device 30. The second coupling member 42 may electrically connect the semiconductor device 30 and the second circuit board 20 while bonding the semiconductor device 30 to the second circuit board 20.

The semiconductor package includes a third coupling member 43 disposed on a lower surface of the first circuit board 10. The third coupling member 43 may electrically connect the first circuit board 10 and the main board while bonding the first circuit board 10 to the main board.

At this time, the first coupling member 41, the second coupling member 42, and the third coupling member 43 may electrically connect between the plurality of components by using at least one bonding method of wire bonding, solder bonding and metal-to-metal direct bonding. That is, since the first coupling member 41, the second coupling member 42, and the third coupling member 43 have a function of electrically connecting a plurality of components, when the metal-to-metal direct bonding is used, the connecting part of the semiconductor package may be understood as an electrically connected portion, not a solder or wire.

The wire bonding method may refer to electrically connecting a plurality of components using a conductive wire such as gold (Au). Also, the solder bonding method may electrically connect a plurality of components using a material containing at least one of Sn, Ag, and Cu. In addition, the metal-to-metal direct bonding method may refer to recrystallization by applying heat and pressure between a plurality of components without the presence of solder, wire, conductive adhesive, etc. In addition, to directly bond between the plurality of components. In addition, the metal-to-metal direct bonding method may refer to a bonding method by the second coupling member 42. In this case, the second coupling member 42 may mean a metal layer formed between a plurality of components by the recrystallization.

Specifically, the first coupling member 41, the second coupling member 42, and the third coupling member 43 may couple a plurality of components to each other by a thermal compression (TC) bonding method. The TC bonding may refer to a method of directly bonding a plurality of components by applying heat and pressure to the first coupling member 41, the second coupling member 42, and the third coupling member 43.

In this case, at least one of the first circuit board 10 and the second circuit board 20 may include a bonding part provided in the electrode on which the first coupling member 41, the second coupling member 42, and the third coupling member 43 are disposed. The bonding part may protrude outward from the first circuit board 10 or the second circuit board 20.

The bonding part may be referred to as a bump, or a post, or a pillar. Preferably, the bonding part may refer to an electrode on which a second coupling member 42 for bonding with the semiconductor device 30 is disposed among the electrodes of the second circuit board 20. That is, as the pitch of the terminals of the semiconductor device 30 becomes finer, a short circuit may occur between the plurality of second connecting parts 1420 that are respectively connected to the plurality of terminals of the semiconductor device 30 by a conductive adhesive such as a solder. Therefore, in the embodiment, thermal compression bonding may be performed to reduce a volume of the second coupling member 42, and in order to secure diffusion prevention and alignment to prevent an intermetallic compound (IMC) formed between a conductive adhesive such as solder and a bonding part from diffusing into the interposer and/or the circuit board, a bonding part may be included in the electrode of the second circuit board 20 on which the second coupling member 42 is disposed.

Referring to FIG. 1b, the semiconductor package of the second embodiment is different from the semiconductor package of the first embodiment in that the connection member 21 is disposed on the second circuit board 20. Recently, the number of signals that semiconductor devices must process is increasing, and accordingly, the size of semiconductor devices is becoming larger. In addition, such large-area semiconductor devices become a problem of lowering the yield of semiconductor devices. Therefore, there is a trend of dividing the pattern size or functional part of semiconductor devices, arranging chip-lets on a circuit board, and burying a connecting member 21 that has the function of electrically connecting the divided chip-lets inside the circuit board. However, the connection member 21 is not limited thereto, and can also connect semiconductor devices with other functions such as memory. For example, the connection member 21 may include a redistribution layer. The connection member 21 may perform a function of electrically connecting a plurality of semiconductor devices horizontally to each other. For example, since the area that a semiconductor device should generally have been too large, the connection member 21 may include a redistribution layer. Since the semiconductor package and the semiconductor device have a large difference in a width or spacing of the circuit pattern, etc., a buffering role of the circuit pattern for electrical connection is required. The buffering role may mean having a size between a width or spacing of the circuit pattern of the semiconductor package and a width or spacing of the circuit pattern of the semiconductor device, and the redistribution layer may include a function of performing the buffering role.

In an embodiment, the connection member 21 may include a silicon material, and include a silicon circuit board and a redistribution layer disposed on the silicon circuit board.

In another embodiment, the connection member 21 may include an organic material. For example, the connection member 21 includes an organic circuit substrate including an organic material instead of the silicon circuit board.

The connection member 21 may be embedded in the second circuit board 20, but is not limited thereto. For example, the connection member 21 may be disposed on the second circuit board 20 to have a protruding structure. In addition, the second circuit board 20 may include a cavity, and the connection member 21 may be disposed in the cavity of the second circuit board 20. The connection member 21 may horizontally connect a plurality of semiconductor devices disposed on the second circuit board 20.

Referring to FIG. 1c, the semiconductor package according to the third embodiment may include a second circuit board 20 and a semiconductor device 30. In this case, the semiconductor package of the third embodiment has a structure in which the first circuit board 10 is removed compared to the semiconductor package of the second embodiment.

That is, the second circuit board 20 of the third embodiment may function as a package substrate while performing an interposer function.

The first coupling member 41 disposed on the lower surface of the second circuit board 20 may couple the second circuit board 20 to the main board of the electronic device.

Referring to FIG. 1d, the semiconductor package according to the fourth embodiment may include a first circuit board 10 and a semiconductor device 30.

In this case, the semiconductor package of the fourth embodiment has a structure in which the second circuit board 20 is removed compared to the semiconductor package of the second embodiment.

That is, the first circuit board 10 of the fourth embodiment can function as a package circuit board while also performing the function of connecting the semiconductor device 30 and a main board. To this end, the first circuit board 10 may include a connection member 11 for connecting the plurality of semiconductor devices. The connection member 11 may be a silicon bridge or an organic material bridge connecting a plurality of semiconductor devices.

Referring to FIG. 1e, the semiconductor package of the fifth embodiment further includes a third semiconductor device 1330 compared to the semiconductor package of the fourth embodiment.

To this end, a fourth coupling member 44 may be disposed on the lower surface of the first circuit board 10. In addition, a third semiconductor device 33 may be disposed on the fourth coupling member 44. That is, the semiconductor package of the fifth embodiment may have a structure in which semiconductor devices are mounted on upper and lower sides, respectively.

In this case, the third semiconductor device 33 may have a structure disposed on the lower surface of the second circuit board 20 in the semiconductor package of FIG. 1c.

Referring to FIG. 1f, the semiconductor package according to the sixth embodiment includes a first circuit board 10.

A first semiconductor device 31 may be disposed on the first circuit board 10. To this end, a first coupling member 41 may be disposed between the first circuit board 10 and the first semiconductor device 31.

In addition, the first circuit board 10 includes a conductive bonding portion 45. The conductive bonding portion 45 may further protrude from the first circuit board 10 toward the second semiconductor device 32. The conductive bonding portion 45 may be referred to as a bump or, alternatively, may also be referred to as a post. The conductive bonding portion 45 may be disposed to have a protruding structure on an electrode disposed at an uppermost side of the first circuit board 10.

A second semiconductor device 32 may be disposed on the conductive bonding portion 45. In this case, the second semiconductor device 32 may be connected to the first circuit board 10 through the conductive bonding portion 45. In addition, a second coupling member 42 may be disposed on the first semiconductor device 31 and the second semiconductor device 32.

Accordingly, the second semiconductor device 32 may be electrically connected to the first semiconductor device 31 through the second coupling member 42.

That is, the second semiconductor device 32 may be connected to the first circuit board 10 through the conductive bonding portion 45, and may be also connected to the first semiconductor device 31 through the second coupling member 42.

In this case, the second semiconductor device 32 may receive a power signal and/or electric power through the conductive bonding portion 45. Also, the second semiconductor device 32 may transmit and receive a communication signal to and from the first semiconductor device 31 through the second coupling member 42.

The semiconductor package according to the sixth embodiment provides a power signal and/or electric power to the second semiconductor device 32 through the conductive bonding portion 45, thereby providing sufficient power for driving the second semiconductor device 32 or enabling smooth control of a power operation.

Accordingly, the embodiment may improve the driving characteristics of the second semiconductor device 32. That is, the embodiment may solve a problem of insufficient power provided to the second semiconductor device 32. Furthermore, in the embodiment, at least one of a power signal, an electric power, and a communication signal of the second semiconductor device 32 are provided through different paths through the conductive bonding portion 45 and the second coupling member 42. Through this, the embodiment can solve the problem that the communication signal is lost due to the power signal. For example, the embodiment may minimize mutual interference between communication signals of power signals.

Meanwhile, the second semiconductor device 32 in the sixth embodiment may have a POP (Package On Package) structure in which a plurality of package substrates are stacked and may be disposed on the first circuit board 10. For example, the second semiconductor device 32 may be a memory package including a memory chip. In addition, the memory package may be coupled on the conductive bonding portion 45. In this case, the memory package may not be connected to the first semiconductor device 31.

Meanwhile, the semiconductor package in the sixth embodiment may include a molding member 46. The molding member 46 may be disposed between the first circuit board 10 and the second semiconductor device 32. For example, the molding member 46 may mold the first coupling member 41, the second coupling member 42, the first semiconductor device 31, and the conductive bonding portion 45.

Referring to FIG. 1g, the semiconductor package according to the seventh embodiment may include a first circuit board 10, a first coupling member 41, a first coupling member 41, a semiconductor device 30, and a third coupling member 43. In this case, the semiconductor package of the seventh embodiment is different from the semiconductor package of the fourth embodiment in that the first circuit board 10 includes a plurality of substrate circuit layers while the connection member 11 is removed.

The first circuit board 10 includes a plurality of circuit board layers. For example, the first circuit board 10 may include a first circuit board layer 10A corresponding to a package substrate and a second circuit board layer 10B corresponding to a redistribution layer of the connection member.

In other words, the semiconductor package of the seventh embodiment may include a first circuit board layer 10A and a second circuit board layer 10B in which the first circuit board (package circuit board, 10) and the second circuit board (interposer, 20) shown in FIG. 1a are integrally formed. A material of the insulating layer of the second circuit board layer 10B may be different from a material of an insulating layer of the first circuit board layer 10A. For example, the material of an insulating layer of the second circuit board layer 10B may include a photocurable material. For example, the second circuit board layer 10B may be a photo imageable dielectric (PID). In addition, since the second circuit board layer 10B includes a photocurable material, it is possible to miniaturize the electrode. Accordingly, in the seventh embodiment, the second circuit board layer 10B may be formed by sequentially stacking an insulating layer of a photo-curable material on the first circuit board layer 10A and forming a miniaturized electrode on the insulating layer of the photo-curable material. Accordingly, the second circuit board layer 10B may include a redistribution layer function including a micro-electrode and may include a function of horizontally connecting a plurality of semiconductor devices 31 and 32.

Hereinafter, a circuit board of an embodiment will be described.

Hereinafter, embodiments will be described in detail with reference to the accompanying drawings. However, regardless of reference numerals, same or corresponding components are assigned with same reference numerals, and redundant descriptions thereof will be omitted.

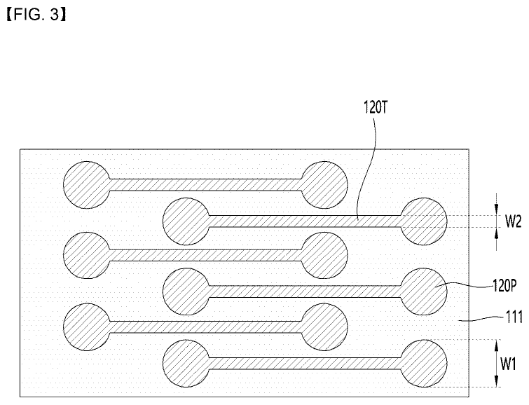

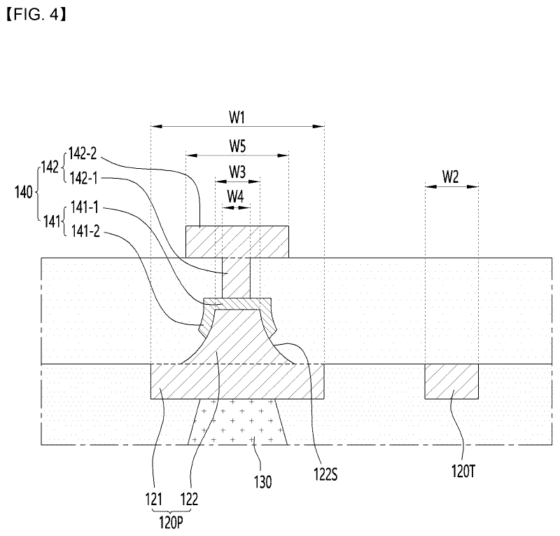

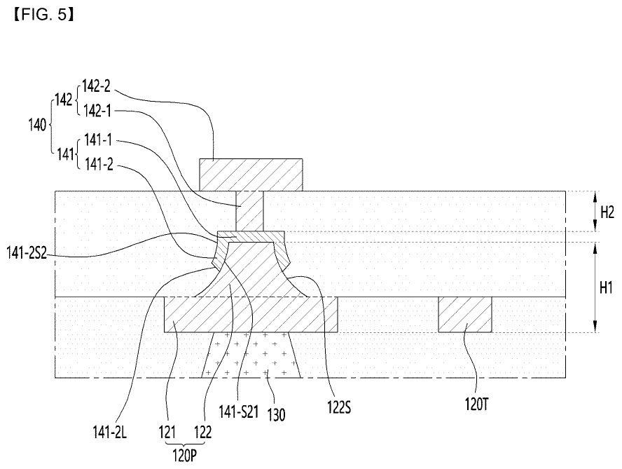

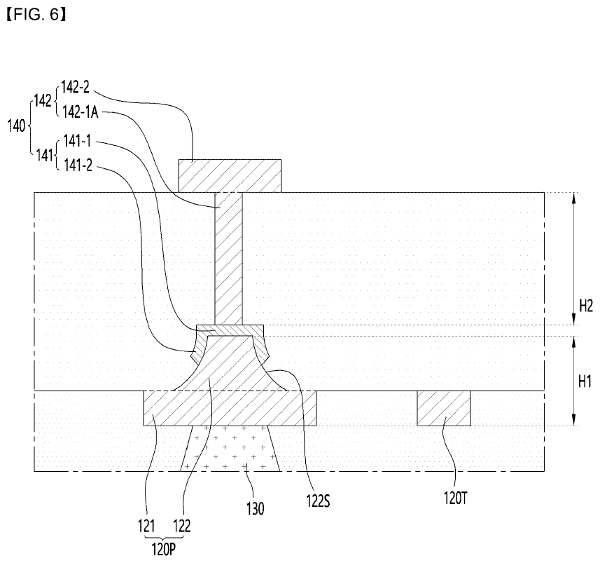

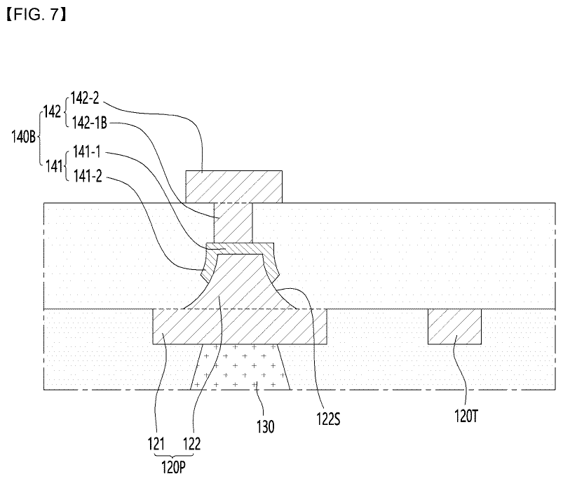

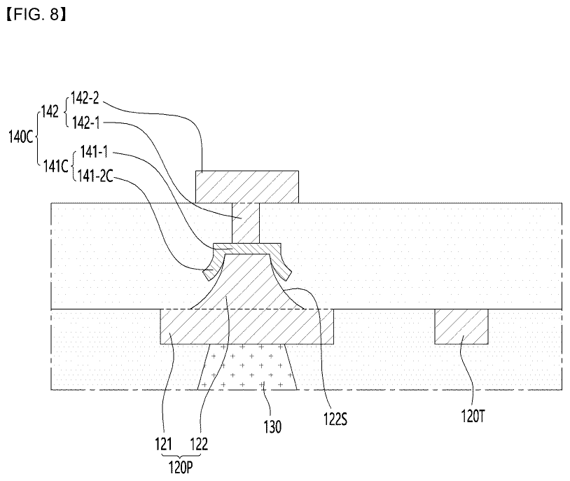

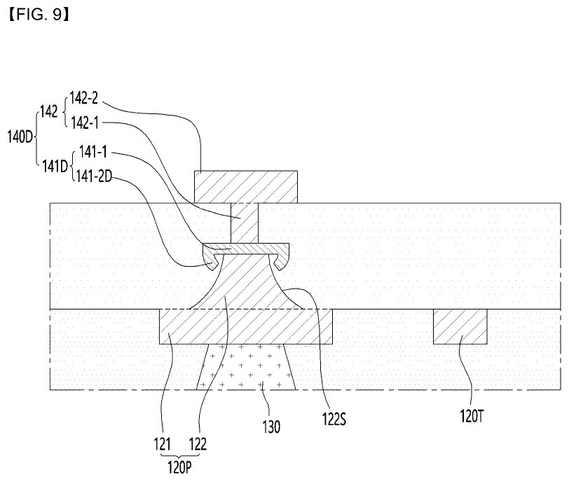

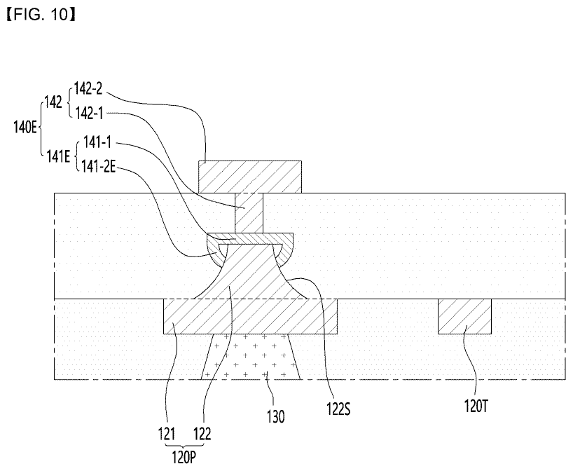

FIG. 2 is a cross-sectional view showing a circuit board according to a first embodiment, FIG. 3 is a plan view of a first electrode provided at an uppermost side of a first insulating layer of FIG. 2, FIG. 4 and FIG. 5 are enlarged views showing a part of a region of the circuit board provided in FIG. 2, FIG. 6 is an enlarged view showing a first modified example of the circuit board of FIG. 2, FIG. 7 is an enlarged view showing a second modified example of the circuit board of FIG. 2, FIG. 8 is an enlarged view showing a third modified example of the circuit board of FIG. 2, FIG. 9 is an enlarged view showing a fourth modified example of the circuit board of FIG. 2, FIG. 10 is an enlarged view showing a fifth modified example of the circuit board of FIG. 2, and FIG. 11 is an enlarged view showing a sixth modified example of the circuit board of FIG. 2.

Hereinafter, a circuit board of the embodiment will be specifically described with reference to FIGS. 2 to 11.

Referring to FIG. 2, a circuit board 100 may include an insulating substrate 110. Specifically, the insulating substrate 110 may refer to a layer including an insulating material among components of the circuit board 100, and may include, for example, an insulating layer 111, a first protective layer 112, and a second protective layer 113.

The insulating layer 111 may be provided for interlayer insulation of a wiring electrode 120 and a via electrode 130. The first protective layer 112 may be an upper protective layer disposed on the insulating layer 111, and the second protective layer 112 may be a lower protective layer disposed under the insulating layer 111. The first protective layer 112 and the second protective layer 113 may include a different material from the insulating layer 111, and may include, for example, a solder resist.

The insulating layer 111 may have a structure in which multiple layers are laminated along a vertical direction. For example, as shown in FIG. 2, the circuit board 100 may have a two-layer structure based on a number of layers of the insulating layer 111, but is not limited thereto. The circuit board 100 of one embodiment may have a number of layers less than two based on the number of layers of the insulating layer 111. The circuit board 100 of another embodiment may have a number of layers of three or more based on the number of layers of the insulating layer 111. Preferably, the circuit board 100 of the embodiment may have a number of layers of five or more, or seven or more, or nine or more based on the number of layers of the insulating layer 111.

When the insulating layer 111 has a multi-layer structure, a plurality of insulating layers 111 may include a same insulating material, but are not limited thereto. For example, at least one of the plurality of insulating layers 111 may include an insulating material different from at least one other insulating material of the plurality of insulating layers 111.

The insulating layer 111 is disposed for vertical insulation between wiring electrodes, which will be described later. For example, a thermosetting insulating material containing an inorganic filler in a resin may be used as the insulating layer 111, and as an example, ABF (Ajinomoto Build-up Film) of Ajinomoto Co., Ltd. may be used. However, the embodiment is not limited thereto, and a photo-curable insulating material (Photo Imageable Dielectric, PID) for forming a fine pattern may be used.

A first protective layer 112 may be disposed on an upper surface of the insulating layer 111, and a second protective layer 113 may be disposed on a lower surface of the insulating layer 111.

The first protective layer 112 can protect an upper surface of the wiring electrode 120 and/or the insulating layer 111 described later from external moisture or contaminants. In addition, when a semiconductor device is disposed on a circuit board 100 using a material such as solder, the first protective layer 112 functions to prevent a short circuit between solders due to low wettability with the solder. The first protective layer 112 can use a photocurable insulating material, and for example, a solder resist can be used. However, the embodiment is not limited thereto, and the first protective layer 112 can include a thermocurable insulating material that is the same insulating material as the insulating layer 111. The first protective layer 112 can include a same insulating material as the insulating layer 111, and for example, can be provided as ABF (Ajinomoto Build-up Film) of Ajinomoto Co., Ltd.

The circuit board 100 may include an electrode part 150.

The electrode part 150 may be disposed on an insulating substrate 110. For example, the electrode part 150 may pass through the insulating substrate 110. For example, a portion of the electrode part 150 may be disposed in the insulating substrate 110, and a remaining portion of the electrode part 150 may protrude above or below a surface of the insulating substrate 110.

The electrode part 150 may include a plurality of electrodes depending on a location or function.

For example, the electrode part 150 may include a wiring electrode 120 and a via electrode 130. The wiring electrode 120 may be disposed on a surface of the insulating layer 111. For example, the wiring electrode 120 may be disposed on an upper surface and/or a lower surface of the insulating layer 111. For example, when the insulating layer 111 includes a first insulating layer and a second insulating layer, the wiring electrode 120 may include a first wiring layer disposed on an upper surface of the first insulating layer, a second wiring layer disposed between the first insulating layer and the second insulating layer, and a third wiring layer disposed on a lower surface of the second insulating layer.

The via electrode 130 may connect between the wiring electrodes 120 disposed in different layers along the vertical direction of the circuit board 100. For example, when the insulating layer 111 has a three-layer structure, the via electrodes 130 may be spaced apart from each other along the vertical direction and may be disposed in each of the three-layer insulating layers 111.

Any one of the plurality of wiring electrodes 120 disposed in different layers may have an ETS (Embedded Trace Substrate) structure. For example, the wiring electrode 120 disposed at an uppermost side of the circuit board 100 may have an ETS structure. Here, a meaning that the wiring electrode 120 has an ETS structure may mean that at least a part of the wiring electrode 120 disposed at an uppermost side has an embedded structure embedded in the insulating layer 111. That is, the embedded structure may mean that at least a part of the wiring electrode 120 overlaps the insulating layer 111 in the horizontal direction. For example, the embedded structure may mean that the lower surface and/or upper surface of the wiring electrode 120 is positioned closer to a lower surface of the insulating layer 111 than an upper surface of the insulating layer 111. In addition, the embedded structure may mean that the lower surface and/or upper surface of the wiring electrode 120 is positioned closer to a lower surface of the second protective layer 113 located under the insulating layer 111 than an upper surface of the insulating layer 111.

The ETS structure is advantageous for miniaturization compared to a wiring electrode having a general protruding structure. Accordingly, the embodiment enables a formation of wiring electrodes corresponding to a size and a pitch of terminals provided in the semiconductor device. Through this, the embodiment can improve the circuit integration. Furthermore, the embodiment can minimize a transmission distance of a signal transmitted through the semiconductor device, thereby minimizing signal transmission loss. In particular,

The wiring electrode 120 may include a pad part 120P and a connection circuit pattern part 120T depending on a position and/or a function.

The pad part 120P may mean a wiring electrode that vertically overlaps with the bonding part 140 among the wiring electrodes 120 disposed at an uppermost side of the circuit board 100. For example, the pad part 120P may mean a wiring electrode in direct contact with the bonding part 140.

The connection circuit pattern part 120T may mean a remaining electrodes excluding the pad part 120P among the wiring electrodes 120. For example, the connection circuit pattern part 120T may mean an electrode electrically connecting between a plurality of pad parts 120P. For example, the connection circuit pattern part 120T may mean a trace connecting between a plurality of pad parts 120P.

The pad part 120P may be divided into a plurality of parts. For example, the pad part 120P may include a first portion 121 overlapping the connection circuit pattern part 120T in a horizontal direction. The first portion 121 of the pad part 120P may be embedded in an insulating layer 111. For example, the first portion 121 of the pad part 120P may have a side surface covered with an insulating layer 111. The pad part 120P may include a second portion 122 provided on the first portion 121. The second portion 122 of the pad part 120P may refer to a portion disposed on the insulating layer 111 among an entire region of the pad part 120P.

At this time, the first portion 121 and the second portion 122 of the pad part 120P may be formed through a plurality of separate processes. For example, the second portion 122 of the pad part 120P may be a copper layer. For example, the second portion 122 of the pad part 120P may be a seed layer for electroplating the first portion 121 of the pad part 120P and the connection circuit pattern part 120T. That is, the first portion 121 of the pad part 120P and the connection circuit pattern part 120T may be an electroplating layer formed by electroplating using the second portion 122 of the pad part 120P as a seed layer.

At this time, a conventional circuit board completely removes a copper layer used as the seed layer. Accordingly, a thickness of a bonding part provided on the electrode of the conventional circuit board may increase. Accordingly, the conventional circuit board may have a difference in height between a plurality of bonding parts that are horizontally spaced apart from each other. Therefore, when bonding a semiconductor device on the bonding part, the conventional circuit board may not stably place the semiconductor device on the bonding part due to the difference in height of the bonding part, and may be bonded in a tilted state in a specific direction.

In contrast, the embodiment may not remove a part of a region where the bonding part 140 is to be disposed among the copper layers used as the seed layer. In addition, an unremoved portion of the copper layers described above may form the second portion 122 of the pad part 120P. An upper surface of the second portion 122 of the pad part 120P may mean an upper surface of the copper layer that is first disposed on a carrier member during a manufacturing process of a circuit board. Accordingly, an upper surface of the second portion 122 of the pad part 120P may be flat. Furthermore, an upper surfaces of the second portions 122 of the plurality of pad parts 120P may be located on a same plane. Accordingly, the embodiment can form a plurality of bonding parts 140 with a uniform thickness by arranging the bonding part 140 on the second portion 122 of the pad part 120P. Furthermore, the embodiment can reduce a thickness of the bonding part 140 by a thickness of the second portion 122 of the pad part 120P. Accordingly, the embodiment can solve a problem of a thickness deviation increasing in proportion to a thickness of the bonding part 140. Accordingly, the embodiment can minimize a height deviation between the plurality of bonding parts 140. Therefore, the embodiment can stably arrange the semiconductor device on the plurality of bonding parts 140. Furthermore, the embodiment can increase a thickness of the bonding part 140 by the thickness of the second portion 122 of the pad part 120P compared to a thickness of the conventional bonding part. Accordingly, the embodiment can secure a height of the bonding part at which the semiconductor device can be stably bonded, and improve the overall physical characteristics and/or electrical characteristics of the semiconductor package accordingly. Accordingly, the semiconductor device can be operated smoothly, and further, a server or an electronic product can be operated smoothly.

The first portion 121 and the second portion 122 of the pad part 120P can include a same metal material. Accordingly, an interface between the first portion 121 and the second portion 122 of the pad part 120P can be difficult to distinguish. Therefore, the first portion 121 and the second portion 122 of the pad part 120P can have a structure in which they are formed integrally with each other. However, the embodiment is not limited thereto. When the interface between the first portion 121 and the second portion 122 of the pad part 120P can be distinguished, the pad part 120P may have a two-layer structure including the first portion 121 and the second portion 122.

The pad part 120P may include a region whose width changes in a vertical direction. The pad part 120P may include a region whose width increases from an upper surface toward a lower surface. Specifically, the first portion 121 and the second portion 122 of the pad part 120P may have different vertical cross-sectional shapes. The first portion 121 of the pad part 120P may be formed by an electrolytic plating process. In addition, the second portion 122 of the pad part 120P may be formed by an etching process. For example, the second portion 122 of the pad part 120P may be formed by a dry etching and/or wet etching process. The interface between the first portion 121 and the second portion 122 of the pad part 120P may be difficult to distinguish, but the distinction may be possible based on a shape of a side surface of the pad part 120P. For example, the pad part 120P may include a side surface 122S having a curvature and/or inclination along a vertical direction, formed by etching. In addition, the side surface 122S having the curvature may be provided at the second portion 122. In addition, the side surface of the first portion 121 may not have a curvature. Through this, the embodiment can distinguish the first portion 121 and the second portion 122 of the pad part 120P through the side surface 122S having the curvature. Here, having a curvature may mean having an inclination in which the width changes (e.g., increases or decreases) along the vertical direction, and not having a curvature may mean that there is little change in the width along the vertical direction.

The pad part 120P may include a first side surface adjacent to a lower surface and having a first inclination. The first side surface may mean a side surface of the first portion 121 of the pad part 120P. The first inclination of the first side surface may be perpendicular to an upper surface of the pad part 120P. For example, an internal angle between the first side surface and the upper surface of the pad part 120P may range from 85 degrees to 95 degrees. In addition, the pad part 120P may include a second side surface 122S adjacent to an upper surface and having a second inclination different from the first inclination. The second side surface may refer to a side surface 122S of the second portion 122 of the pad part 120P. The second side surface 122S may be a curved surface having a specific curvature and/or inclination along the vertical direction. The second side surface 122S may have a curvature corresponding to an etching process condition of a copper layer used for electroplating the first portion 121 of the pad part 120P. The pad part 120P may have a different width from the connection circuit pattern part 120T. The width may refer to a horizontal distance in a horizontal direction perpendicular to the vertical direction of the circuit board 100. Preferably, a width of the pad part 120P may refer to a horizontal distance in a region having a largest width among the entire regions of the pad part 120P in the vertical direction. In addition, a width of the connection circuit pattern part 120T may mean a horizontal distance in a horizontal direction in a region having a largest width among the entire regions in the vertical direction of the connection circuit pattern part 120T.

A width of the pad part 120P may mean a width of the first portion 121 of the pad part 120P. For example, a width of the pad part 120P may mean a width of a lower surface of the pad part 120P.

Furthermore, a planar shape of the pad part 120P may be a circular shape. In another embodiment, a planar shape of the pad part 120P may be an elliptical shape. In addition, when the planar shape of the pad part 120P is a circular shape, a width of the pad part 120P may mean a diameter of the pad part 120P. In addition, when a planar shape of the pad part 120P is an elliptical shape, a width of the pad part 120P may mean a diameter in an long axis direction of the pad part 120P.

Referring to FIG. 3, a width W1 of the pad part 120P may have a range of 40 μm to 70 μm. Preferably, the width W1 of the pad part 120P may have a range of 42 μm to 68 μm. More preferably, the width W1 of the pad part 120P may have a range of 45 μm to 65 μm. If the width W1 of the pad part 120P is less than 40 μm, electrical connectivity with a chip mounted on a circuit board may be deteriorated. If the width W1 of the pad part 120P is smaller than 40 μm, an allowable current of a signal transmitted through the pad part 120P may be reduced. In addition, when the allowable current is reduced, signal transmission characteristics may be deteriorated. If the width W1 of the pad part 120P exceeds 70 μm, it may be difficult to place all of pad parts connected to each of terminals of the semiconductor device within a limited space. If the width W1 of the pad part 120P exceeds 70 μm, a volume of the circuit board and a volume of the semiconductor package may increase.

Meanwhile, a width W2 of the connection circuit pattern part 120T may have a range of 2 μm to 20 μm. Preferably, the width W2 of the connection circuit pattern part 120T may have a range of 2.2 μm to 18 μm. More preferably, the width W2 of the connection circuit pattern part 120T may have a range of 2.5 μm to 15 μm.

If the width W2 of the connection circuit pattern part 120T is smaller than 2 μm, a signal resistance of the connection circuit pattern part 120T increases, and thus normal communication with the chip disposed on the circuit board may be difficult. In addition, if the width W2 of the connection circuit pattern part 120T is smaller than 2 μm, it is not only difficult to implement, but also a reliability problem may occur in which the connection circuit pattern part 120T easily collapses during a manufacturing process. In addition, if the width W2 of the connection circuit pattern part 120T exceeds 20 μm, it may be difficult to place all of the connection circuit pattern parts 120T connected to the pad part 120P within a limited space. If the width W2 of the connection circuit pattern part 120T exceeds 20 μm, the volume of the circuit board and the semiconductor package may increase, and thus, thinning may be difficult.

The electrode part 150 may include a bonding part 140. The bonding part 140 may be disposed on the wiring electrode 120. Preferably, the bonding part 140 may be disposed on the pad part 120P of the wiring electrode 120.

The bonding part 140 may include a conductive metal part 141 disposed on the pad part 120P and a coupling portion 142 disposed on the conductive metal part 141.

The conductive metal part 141 may be disposed on the pad part 120P. The conductive metal part 141 may be disposed on the second portion 122 of the pad part 120P. The conductive metal part 141 may include a metal material different from a metal material constituting the pad part 120P. For example, the conductive metal part 141 may include a second metal material capable of selective etching with the first metal material constituting the pad part 120P. In this case, the meaning that the first metal material and the second metal material are capable of selective etching may mean that the second metal material is not etched when an etching process is performed with an etching solution capable of etching the first metal material.

Referring to FIG. 4, a width of the conductive metal part 141 may be larger than a width W3 of an upper surface of the pad part 120P. The width of the conductive metal part 141 may mean a horizontal distance from a left end to a right end of the conductive metal part 141. The width of the conductive metal part 141 may mean a length of the upper surface of the conductive metal part 141. The width of the conductive metal part 141 may satisfy a range of 110% to 180% of the width W3 of the upper surface of the pad part 120P. Preferably, the width of the conductive metal part 141 may satisfy a range of 112% to 170% of the width W3 of the upper surface of the pad part 120P. More preferably, the width of the conductive metal part 141 can satisfy a range of 115% to 150% of the width W3 of the upper surface of the pad part 120P. If the width of the conductive metal part 141 is less than 110% of the width W3 of the upper surface of the pad part 120P, processability in a process of forming the second portion 122 of the pad part 120P by an etching process may be deteriorated. For example, if the width of the conductive metal part 141 is less than 110% of the width W3 of the upper surface of the pad part 120P, the pad part 120P may not have a constant thickness, and thus an effect achieved by a structure of the embodiment may be insufficient. For example, if the width of the conductive metal part 141 is less than 110% of the width W3 of the upper surface of the pad part 120P, the width W3 of the upper surface of the pad part 120P may become excessively small. In addition, if the width W3 of the upper surface of the pad part 120P becomes excessively small, a vertical cross-section of the second portion 122 of the pad part 120P may have a shape close to a triangle, and thus the coupling portion 142 of the bonding part 140 may not be stably disposed on the pad part 120P. In addition, if the width of the conductive metal part 141 exceeds a range of 180% of the width W3 of the upper surface of the pad part 120P, a width of a region area that does not vertically overlap the upper surface of the pad part 120P among an entire region of the conductive metal part 141 may increase. In addition, when the width of the region of the conductive metal part 141 that does not vertically overlap with the upper surface of the pad part 120P increases, the conductive metal part 141 may come into contact with the connection circuit pattern part 120T or another pad part adjacent to the pad part 120P, and an electrical short problem may occur due to this. In addition, when the width of the conductive metal part 141 exceeds a range of 180% of the width W3 of the upper surface of the pad part 120P, a problem may occur in which a part of the region of the second portion 122 of the pad part 120P that does not vertically overlap with the first portion 121 of the pad part 120P is not removed by etching. As a result, an electrical short problem may occur due to electrical connection between an adjacent pad part 120P and the connection circuit pattern part 120T or a plurality of adjacent pad parts due to at least a part of the second portion 122 not being etched.

The conductive metal part 141 can be divided into a plurality of parts. The conductive metal part 141 can include a contact portion 141-1 in contact with the upper surface of the pad part 120P. The contact portion 141-1 of the conductive metal part 141 can vertically overlap with the upper surface of the pad part 120P. Through this, the embodiment can enable the coupling portion 142 to be stably coupled on the conductive metal part 141. Specifically, the conductive metal part 141 can include a metal material that increases the bonding force between the pad part 120P and the coupling portion 142. Through this, a problem of the coupling portion 142 being peeled off from the pad part 120P can be solved.

The conductive metal part 141 may include an extension portion 141-2 extending from the contact portion 141-1 of the pad part 120P in an outward direction. The extension portion 141-2 of the conductive metal part 141 may not overlap an upper surface of the pad part 120P in a vertical direction. The extension portion 141-2 of the conductive metal part 141 may overlap a side surface 122S of the pad part 120P in a vertical direction. Preferably, the extension portion 141-2 of the conductive metal part 141 may overlap a side surface 122S of the pad part 120P having a curvature in a vertical direction. Since the side surface 122S of the pad part 120P has a curvature, an area of an upper surface of the pad part 120P may decrease according to the curvature. At this time, the extension portion 141-2 of the conductive metal part 141 can improve a contact area with the coupling portion 142 by overlapping the side surface 122S having the curvature in a vertical direction. Through this, the embodiment can further improve the bonding strength between the coupling portion 142 and the pad part 120P.

At this time, the extension portion 141-2 of the conductive metal part 141 can be bent with a curvature corresponding to the curvature of the side surface 122S of the pad part 120P. Through this, the extension portion 141-2 can minimize a difference between a width of an upper surface and a width of a lower surface of the second portion 122 of the pad part 120P. Accordingly, the embodiment can prevent a reduction of the signal characteristics caused by the difference in the width of the upper surface and the lower surface of the second portion 122. Through this, the embodiment can further improve the operational reliability of the semiconductor package.

Accordingly, the extension portion 141-2 of the conductive metal part 141 may be provided to surround the side surface 122S of the pad part 120P. For example, the extension portion 141-2 may include an inner surface 141-2S1 facing the side surface 122S of the pad part 120P and an outer surface 141-2S2 opposite to the inner surface 141-2S1. In addition, the extension portion 141-2 may include a lower surface 141-2L between the inner surface 141-2S1 and the outer surface 141-2S2. Through this, the embodiment can solve a problem in which the extension portion 141-2 of the conductive metal part 141 is separated from the contact portion 141-1. Furthermore, the embodiment can prevent the extension portion 141-2 of the conductive metal part 141 from coming into contact with another electrode part adjacent thereto even if the extension portion 141-2 of the conductive metal part 141 is separated from the contact portion 141-1. Through this, the embodiment can further improve the electrical reliability of the semiconductor package.

At this time, the inner surface 141-2S1 of the extension portion 141-2 can be in contact with the side surface 122S of the pad part 120P having a curvature. For example, an entire region of the inner surface 141-2S1 can be in contact with the side surface 122S of the pad part 120P.

In addition, the outer surface 141-2S2 of the extension portion 141-2 can be covered with the first protective layer 112. For example, the outer surface 141-2S2 of the extension portion 141-2 can be in direct contact with the first protective layer 112. The lower surface 141-2L of the extension portion 141-2 may not be in contact with the side surface 122S of the pad part 120P. For example, the lower surface 141-2L of the extension portion 141-2 may be in contact with the first protective layer 112. The outer surface 141-2S2 and the lower surface 141-2L of the extension portion 141-2 of the conductive metal part 141 of the first embodiment may be in contact with the first protective layer 112, and the inner surface 141-2S1 of the extension portion 141-2 may be in contact with the side surface 122S of the pad part 120P having a curvature. Accordingly, a contact area between the electrode part 150 and the first protective layer 112 can be increased by the extension portion 141-2 of the conductive metal part 141, and thus the adhesion between the electrode part 150 and the first protective layer 112 can be improved.

The bonding part 140 may include a coupling portion 142 disposed on the conductive metal part 141. The coupling portion 142 may include a through portion 142-1 disposed on the conductive metal part 141 and a protruding portion 142-2 disposed on the through portion 142-1. Therefore, the bonding part 140 may have a structure in which the conductive metal part 141, the through portion 142-1, and the protruding portion 142-2 are laminated along a vertical direction.

The through portion 142-1 may pass through at least a part of the first protective layer 112. For example, the second portion 122 of the pad part 120P, the conductive metal part 141, and the through portion 142-1 may be a through electrodes passing through the first protective layer 112. In addition, the through portion 142-1 may be a part of the through electrode passing through the first protective layer 112.

The width W4 of the through portion 142-1 may be smaller than the width of the conductive metal part 141. At this time, the width of the conductive metal part 141 may mean a length in a horizontal direction including the contact portion 141-1 and the extension portion 141-2 of the conductive metal part 141. The contact portion 141-1 of the conductive metal part 141 may mean a portion that vertically overlaps with the upper surface of the pad part 120P, and the extension portion 141-2 of the conductive metal part 141 may mean a portion that vertically overlaps with the side surface 122S having a curvature but does not vertically overlap with the upper surface of the pad part 120P. Through this, a boundary between the contact portion 141-1 and the extension portion 141-2 of the conductive metal part 141 may be distinguished.

The width W4 of the through portion 142-1 may be smaller than the width of the contact portion 141-1 of the conductive metal part 141. When the width W4 of the through portion 142-1 is larger than the width of the conductive metal part 141, a height deviation may occur between the plurality of coupling portions 142. For example, if the width W4 of the through portion 142-1 is larger than the width of the conductive metal part 141, a thickness deviation and/or the height deviation between the plurality of bonding parts spaced apart from each other may increase, and thus bondability with the semiconductor device may deteriorate. In addition, if the width W4 of the through portion 142-1 is larger than the width of the conductive metal part 141, a spacing between the plurality of neighboring through portions may decrease, and thus the signal transmission loss may increase due to the increase in signal interference therebetween.

The width W4 of the through portion 142-1 may be smaller than the width W3 of the upper surface of the pad part 120P. For example, the width W4 of the through portion 142-1 may be smaller than the width W3 of the upper surface of the second portion 122 of the pad part 120P. If the width W4 of the through portion 142-1 is larger than the width W3 of the upper surface of the pad part 120P, a height deviation of the coupling portion 142 may increase. For example, if the width W4 of the through portion 142-1 is larger than the width W3 of the upper surface of the pad part 120P, a thickness deviation and/or the height deviation between a plurality of bonding parts spaced apart from each other may increase, and thus the bondability with the semiconductor device may deteriorate. In addition, if the width W4 of the through portion 142-1 is larger than the width W3 of the upper surface of the pad part 120P, a spacing between the plurality of adjacent through portions decreases, and thus, signal transmission loss may increase due to the increase in signal interference therebetween

The coupling portion 142 may include a protruding portion 142-2 disposed on the through portion 142-1. The through portion 142-1 and the protruding portion 142-2 may be formed integrally with each other. In addition, the through portion 142-1 may mean a region overlapping the first protective layer 112 in a horizontal direction, and the protruding portion 142-2 may mean a region that does not overlap the first protective layer 112 in a horizontal direction. For example, the protruding portion 142-2 may mean a portion protruding above the upper surface of the first protective layer 112. The protruding portion 142-2 may refer to a portion bonded with a conductive adhesive such as solder. The width W5 of the protruding portion 142-2 may be smaller than the width W1 of the lower surface of the pad part 120P. Specifically, the width W5 of the protruding portion 142-2 may be smaller than the width W1 of the lower surface of the first portion 121 of the pad part 120P. If the width W5 of the protruding portion 142-2 is larger than the width W1 of the lower surface of the pad part 120P, a spacing between the plurality of bonding parts spaced apart from each other may be reduced. In addition, if the spacing between the plurality of bonding parts is reduced, an electrical circuit short problem may occur due to the solders disposed on the bonding parts adjacent to each other being connected to each other.

According to the embodiment of FIG. 5, a vertical length H1 of the pad part 120P of the embodiment may be different from a vertical length H2 of the through portion 142-1. In one embodiment, the vertical length H1 of the pad part 120P may be greater than the vertical length H2 of the through portion 142-1. That is, the embodiment may reduce the vertical length H2 of the through portion 142-1 by the vertical length of the second portion 122 by allowing the pad part 120P to include the second portion 122. Accordingly, the embodiment may allow the vertical length H2 of the through portion 142-1 to be smaller than the vertical length H1 of the pad part 120P. In addition, since the vertical length H2 of the through portion 142-1 is smaller than the vertical length H1 of the pad part 120P, the vertical lengths of each of the plurality of bonding parts can be uniformly adjusted.

According to the embodiment of FIG. 6, the vertical length H1 of the pad part 120P of the embodiment can be different from the vertical length H2 of the through portion 142-1A of the coupling portion 142.

In one embodiment, the vertical length H1 of the pad part 120P can be smaller than the vertical length H2′ of the through portion 142-1A. That is, the embodiment can improve a flatness of the upper surface of the pad part 120P by allowing the pad part 120P to have the second portion 122. Accordingly, even if the through portion 142-1A having a vertical length H2′ greater than the vertical length H1 of the pad part 120P is formed, the embodiment can uniformly match the vertical lengths of each of the plurality of bonding parts. That is, the embodiment can minimize the height deviation between the plurality of coupling portions 142 by the pad part 120P including the second portion 122 even if the vertical length H2 of the through portion 142-1A increases.

The wiring electrode 120, the via electrode 130, and the coupling portion 142 can be formed of at least one metal material selected from gold (Au), silver (Ag), platinum (Pt), titanium (Ti), tin (Sn), copper (Cu), and zinc (Zn). In addition, the wiring electrode 120, the via electrode 130, and the coupling portion 142 may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the wiring electrode 120, the via electrode 130, and the coupling portion 142 may be formed of copper (Cu) having high electrical conductivity and a relatively low price.

The conductive metal part 141 may include a different metal material from the wiring electrode 120, the via electrode 130, and the coupling portion 142. Preferably, the conductive metal part 141 of the electrode part 150 may include a metal material different from a metal material of the wiring electrode 120. For example, the conductive metal part 141 may include a metal material of nickel (Ni), palladium (Pd), gold (Au), and titanium (Ti), which are different from the metal material constituting the wiring electrode 120. For example, the second portion 122 of the pad part 120P of the electrode part 150 may include copper, and may be etched with an etchant such as H₂SO₄ in an etching process. The conductive metal part 141 may include a metal material that is not etched by the etchant such as H₂SO₄. When the conductive metal part 141 includes nickel, the adhesion between the pad part 120P and the coupling portion 142 may be improved, and thereby the bonding force between the pad part 120P and the coupling portion 142 may be increased.

The via electrode 130 of the electrode part 150 can be formed by filling an inside of the through hole provided in the insulating substrate 110 with a conductive material. The through hole can be formed by any one of the processing methods among mechanical, laser, and chemical processing. When the through hole is formed by mechanical processing, methods such as milling, drilling, and routing can be used. In addition, when the through hole is formed by laser processing, a UV or CO2 laser method can be used. In addition, when the through hole is formed by chemical processing, a chemical including aminosilane, ketones, etc. can be used.

Hereinafter, a structure of another embodiment will be described based on the structure of the described circuit board. In the circuit board of the embodiment below, a detailed description of the portion that is substantially the same as the structure of the circuit board described previously will be omitted.

Meanwhile, referring to FIG. 7, a structure of the bonding part 140B of the circuit board may be different from that of the embodiment described previously.

That is, the bonding part 140 of the previous embodiment includes the conductive metal part 141 and the coupling portion 142, and the through portion 142-1 does not overlap with the side surface 122S having the curved surface of the pad part 120P in the vertical direction. In other words, the through portion 142-1 of the previous embodiment overlaps entirely with the upper surface of the pad part 120P in the vertical direction.

In another embodiment, the bonding part 140 may include a conductive metal part 141 and a coupling portion 142B. In addition, the conductive metal part 141 may include a contact portion 141-1 and an extension portion 141-2. In addition, the coupling portion 142B may include a through portion 142-1B and a protruding portion 142-2.

At this time, the through portion 142-1B may be disposed to be offset to one side on the conductive metal part 141. For example, a central axis in a horizontal direction of the through portion 142-1B may be misaligned with a central axis in a horizontal direction of the conductive metal part 141. This may be because the conductive metal part 141 includes a contact portion 141-1 and an extension portion 141-2, and a width of the conductive metal part 141 is larger than the width of the upper surface of the pad part 120P due to the extension portion 141-2.

Therefore, in the embodiment, when forming the through portion 142-1B, the through portion 142-1B may be disposed to be biased to one side on the pad part 120P. Accordingly, the through portion 142-1B may include a portion overlapping the side surface 122S having a curved surface of the pad part 120P in the vertical direction. For example, the through portion 142-1B may include a first portion overlapping the upper surface of the pad part 120P in the vertical direction, and a second portion overlapping the side surface 122S having a curved surface of the pad part 120P in the vertical direction.

Through this, the embodiment can increase a spacing between the plurality of through portions 142-1B adjacent to each other, and further, a spacing between the plurality of coupling portions 142B adjacent to each other. In addition, the embodiment can increase an amount of conductive adhesive disposed on the coupling portion 142B by increasing the spacing between the coupling portions 142B, thereby improving the bonding strength between the semiconductor device and the circuit board.

Meanwhile, referring to FIG. 8, the embodiment can include a bonding part 140C. The bonding part 140C can include a conductive metal part 141C and a coupling portion 142.

The conductive metal part 141C can include a contact portion 141-1 vertically overlapping the upper surface of the pad part 120P. In addition, the conductive metal part 141C can include an extension portion 141-2C that is bent and extended downward from the contact portion 141-1. At this time, an inner surface of the extension portion 141-2 of the previous embodiment may be in contact with the side surface 122S having the curved surface of the pad part 120P as a whole.

Unlike this, an inner surface of the extension portion 141-2C may partially contact the side surface 122S having the curvature of the pad part 120P. For example, the extension portion 141-2C may be bent in a bending direction corresponding to the curvature of the side surface 122S of the pad part 120P. However, a curvature of the inner surface of the extension portion 141-2C may be different from the curvature of the side surface 122S of the pad part 120P. Accordingly, the inner surface of the extension portion 141-2C may include a first portion in contact with the side surface 122S of the pad part 120P having the curvature, and a second portion spaced apart from the side surface 122S of the pad part 120P. In addition, a certain separation space may be provided between the second portion of the inner surface of the extension portion 141-2C and the side surface 122S of the pad part 120P. At this time, the first protective layer 112 may be provided to fill the separation space. At this time, the separation space may function as an anchor that improves the bonding force with the first protective layer 112. Through this, the embodiment may increase the adhesion between the insulating layer 111 and the first protective layer 112 and the adhesion between the first protective layer 112 and the bonding part 140C.

Meanwhile, as a modified example thereof, the inner surface of the extension portion 141-2C may include only the second portion. For example, the inner surface of the extension portion 141-2C may not entirely contact the side surface 122S of the pad part 120P having a curved surface. For example, the inner surface of the extension portion 141-2C may be in contact with the first protective layer 112 as a whole.

According to the embodiment of FIG. 9, the embodiment may include a bonding part 140D. The bonding part 140D may include a conductive metal part 141D and a coupling portion 142. The conductive metal part 141D may include a contact portion 141-1 vertically overlapping the upper surface of the pad part 120P. In addition, the conductive metal part 141D may include an extension portion 141-2D that is bent and extended downward from the contact portion 141-1. The inner surface of the extension portion 141-2D may not be in contact with the side surface 122S of the pad part 120P having the curvature as a whole. For example, the extension portion 141-2D may be bent in a bending direction different from the curvature of the side surface 122S of the pad part 120P. However, the curvature of the inner surface of the extension portion 141-2D may be different from the curvature of the side surface 122S of the pad part 120P. Therefore, the inner surface of the extension portion 141-2C may not contact the side surface 122S of the pad part 120P having the curvature. At this time, a lower surface of the extension portion 141-2D may also not contact the side surface 122S of the pad part 120P. For example, all of the inner surface, the outer surface, and the lower surface of the extension portion 141-2D may all contact the first protective layer 112.

According to the embodiment of FIG. 10, the embodiment may include a bonding part 140E. The bonding part 140E may include a conductive metal part 141E and a coupling portion 142.

The conductive metal part 141E may include a contact portion 141-1 vertically overlapping an upper surface of the pad part 120P. In addition, the conductive metal part 141E may include an extension portion 141-2E that is bent and extended downward from the contact portion 141-1. The inner surface of the extension portion 141-2E may not entirely contact the side surface 122S of the pad part 120P having a curvature. For example, the extension portion 141-2E may be bent in a bending direction different from that of the curvature of the side surface 122S of the pad part 120P. However, the curvature of the inner surface of the extension portion 141-2E may be different from the curvature of the side surface 122S of the pad part 120P. Therefore, the inner surface of the extension portion 141-2E may not contact the side surface 122S of the pad part 120P having the curvature. In addition, the lower surface of the extension portion 141-2E may contact the side surface 122S of the pad part 120P having the curvature. That is, the lower surface corresponding to an end portion of the extension portion 141-2E according to a length in the horizontal direction of the extension portion 141-2E may contact the side surface 122S of the pad part 120P.

According to the embodiment of FIG. 11, the embodiment may include a bonding part 140F. The bonding part 140F may include a conductive metal part 141F and a coupling portion 142.

The conductive metal part 141F may include a contact portion 141-1 vertically overlapping the upper surface of the pad part 120P. In addition, the conductive metal part 141F may include an extension portion 141-2F that is bent and extended downwardly from the contact portion 141-1. The extension portion 141-2F may not horizontally overlap with the side surface 122S of the pad part 120P. For example, the extension portion 141-2F may extend horizontally from the contact portion 141-1 instead of downwardly. That is, the extension portion 141-2F may overlap with the side surface 122S of the pad part 120P in the vertical direction but may not overlap in the horizontal direction.

The circuit board of the above-described embodiment of the embodiment can minimize a height deviation between a plurality of bonding parts connected to coupling members. Specifically, the circuit board of the embodiment can include a pad part. The pad part can include a first portion embedded in an insulating layer and a second portion provided on the first portion and protruding on the insulating layer. In addition, the circuit board can include a connection circuit pattern part corresponding to a trace that overlaps the first portion of the plurality of pad parts in a horizontal direction. At this time, the second portion of the pad part can be a seed layer for forming the first portion of the pad part and the connection circuit pattern part by electrolytic plating.

Specifically, a conventional circuit board completely removes a copper layer used as the seed layer. Accordingly, a thickness of the bonding part provided on the pad part in the conventional circuit board can increase. As a result, the conventional circuit board can have a height deviation between the plurality of bonding parts that are spaced apart from each other in a horizontal direction. Accordingly, when bonding a semiconductor device onto a bonding part, the conventional circuit board may not stably place the semiconductor device on the bonding part due to a height difference between the plurality of bonding parts and may be bonded in a state of being tilted in a specific direction. In contrast, the embodiment may not remove a part of a region of a copper layer used as a seed layer where the bonding part is to be disposed, thereby allowing the pad part to have a second portion, which is a part of the copper layer that has not been removed as described above. At this time, an upper surface of the second portion of the pad part may mean an upper surface of a copper layer that is preferentially disposed on a carrier member during a manufacturing process of the circuit board. Accordingly, an upper surface of the second portion of the pad part may be flat. Furthermore, upper surfaces of the second portions of the plurality of pad parts may be positioned on a same plane. Therefore, the embodiment may form a plurality of bonding parts with a uniform thickness and/or height by arranging a bonding part on the second portion of the pad part. Furthermore, the embodiment may reduce a thickness of the bonding part by a thickness of the second portion of the pad part. Accordingly, the embodiment can solve a problem that a thickness deviation between the plurality of bonding parts increases in proportion to a thickness of the bonding part. Accordingly, the embodiment can minimize the height deviation between the plurality of bonding parts. Therefore, the embodiment can stably dispose the semiconductor device on the plurality of bonding parts. Furthermore, the embodiment can increase a thickness of the bonding part by a thickness of the second portion of the pad part compared to a thickness of a conventional bonding part. Furthermore, the embodiment can minimize a thickness deviation between the plurality of bonding parts by forming the bonding part using a pad part having a uniform height even if the thickness of the bonding part is increased.

Accordingly, the embodiment can secure a height of the bonding part at which the semiconductor device can be stably bonded, and can improve overall physical characteristics and/or electrical characteristics of the semiconductor package. Accordingly, the semiconductor device can be operated smoothly, and further, a server or an electronic product can be operated smoothly.

In addition, the bonding part may include a through portion passing through at least a portion of a region of the protective layer from an upper surface of the protective layer, and a bonding portion disposed on the through portion and protruding onto the protective layer. The second portion of the pad part may include a side surface having a curvature. The through portion of the bonding part may overlap the side surface having the curvature of the pad part in a vertical direction. Therefore, when forming the through portion of the bonding part, the embodiment may allow the through-portion to be biased to one side on the pad part. Through this, the embodiment may increase a spacing between a plurality of through portions adjacent to each other, and further, between a plurality of bonding parts adjacent to each other. The embodiment may increase an amount of coupling members disposed on the bonding part by increasing the spacing between the bonding parts, thereby improving a bonding strength between the semiconductor device and the circuit board.

In addition, a conductive metal part of the bonding part may include a contact portion overlapping an upper surface of the pad part in a vertical direction, and an extension portion overlapping a side surface of the pad part having the curvature in a vertical direction. The extension portion may be bent in a bending direction corresponding to the curvature of the side surface of the pad part from the contact portion. Through this, the embodiment may increase a contact area between the protective layer and the pad part by using the extension portion, thereby improving the bonding force between the protective layer and the pad part.

In addition, at least a part of an inner surface of the extension portion of the conductive metal part may not be in contact with the side surface of the pad part. Through this, a certain separation space may be provided between the side surface of the pad part and the inner surface of the extension portion. At this time, the protective layer may be provided to fill the separation space. At this time, the separation space may function as an anchor that improves the bonding force with the protective layer. Through this, the embodiment may improve an adhesion between the insulating layer and the protective layer and an adhesion between the protective layer and the bonding part.

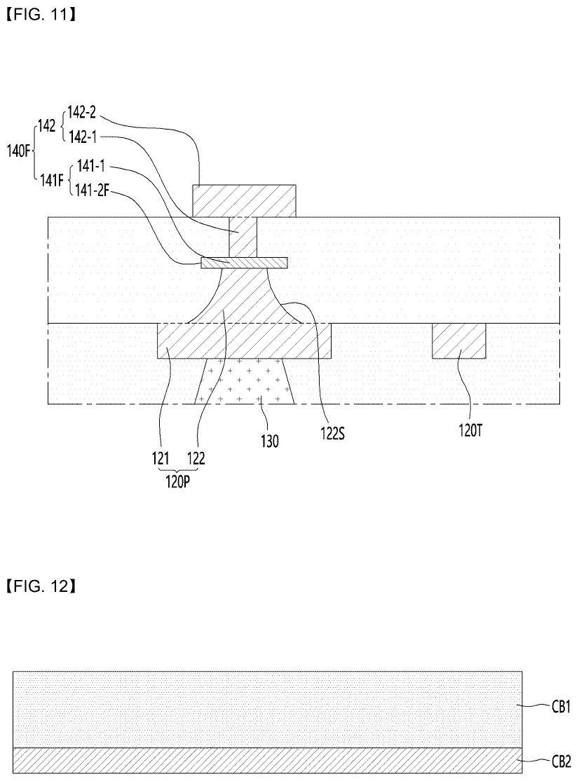

FIGS. 12 to 23 are cross-sectional views showing a manufacturing method of a circuit board illustrated in FIG. 2 in order of processes.

Referring to FIG. 12, the embodiment may prepare a carrier board. For example, the embodiment may prepare a carrier board in which a carrier insulating layer CB1 and a metal layer CB2 are disposed on at least one surface of the carrier insulating layer CB1. At this time, the metal layer CB2 may be disposed on only one of first and second surfaces of the carrier insulating layer CB1, or alternatively, may be disposed on both surfaces. For example, the metal layer CB2 may be disposed on only one surface of the carrier insulating layer CB1, and thus, a manufacturing process of the circuit board may be performed on only one surface. In another embodiment, the metal layer CB2 may be disposed on both surfaces of the carrier insulating layer CB1, and thus, a process of manufacturing a plurality of circuit boards may be performed simultaneously on both surfaces of the carrier board.

The metal layer CB2 may be formed by electroless plating the carrier insulating layer CB1. Alternatively, the carrier insulating layer CB1 and the metal layer CB2 may be CCL (Copper Clad Laminate). That is, the metal layer CB2 may be a copper layer. For example, the metal layer CB2 may be a copper foil. For example, the metal layer CB2 may be an electroless plating layer formed on the carrier insulating layer CB1. That is, the metal layer CB2 may be a metal layer formed first in a process of manufacturing a circuit board. The metal layer CB2 may constitute the second portion 122 of the pad part 120P among the wiring electrodes 120. The metal layer CB2 may be a seed layer for electrolytic plating the first portion 121 of the pad part 120P and the connection circuit pattern part 120T. The metal layer CB2 may have a certain thickness. The metal layer CB2 may be composed of one layer, or may be composed of at least two layers. Through this, a thickness of the second portion 122 of the pad part 120P may be secured. When the metal layer CB2 is composed of two or more layers, one of the layers may be a copper layer and another layer may be an electroless plating layer.

Next, referring to FIG. 13, the embodiment may proceed with a process of forming a wiring electrode 120 under a metal layer CB. Preferably, the embodiment may proceed with a process of forming a first portion 121 of a pad part 120P and a connection circuit pattern part 120T by performing electrolytic plating on the metal layer CB2 as a seed layer. To this end, a mask M1 including an open region corresponding to a region where the first portion 121 of the pad part 120P and the connection circuit pattern part 120T are to be disposed can be disposed under the metal layer CB2.

At this time, in the embodiment, a curing process of heat-treating the mask M1 can be additionally performed before the electrolytic plating process of the first portion 121 of the pad part 120P and the connection circuit pattern part 120T. For example, in the embodiment, a process of curing the mask M1 can be performed after the exposure and development processes of the mask M1. The curing of the mask M1 may include curing using ultraviolet rays and curing using infrared rays. For example, in the embodiment, the mask M1 may be cured using ultraviolet rays in a range of 5 mV to 100 mV. Alternatively, in the embodiment, the mask M1 may be cured using infrared heat. As described above, in the embodiment, the bonding strength between the metal layer CB2 and the mask M1 may be improved by additionally performing a process of curing the mask M1. Accordingly, in the embodiment, the first portion 121 of the pad part 120P and the connection circuit pattern part 120T may be refined according to the improved bonding strength between the mask M1 and the metal layer CB2.

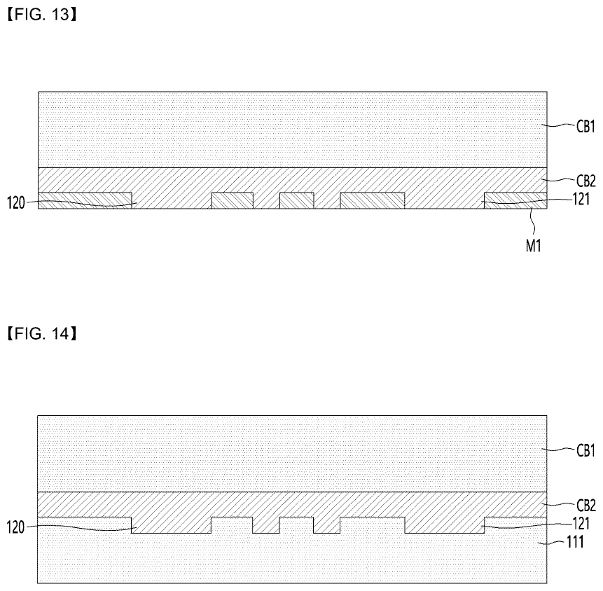

Next, referring to FIG. 14, the embodiment may remove the mask M1. Thereafter, the embodiment may perform a process of preprocessing the first portion 121 of the pad part 120P and the connection circuit pattern part 120T. For example, the embodiment may proceed with a process of providing a surface roughness of a certain level or higher to surfaces of the first portion 121 of the pad part 120P and the connection circuit pattern part 120T. For example, in the embodiment, a side surface and a lower surface of each of the first portion 121 of the pad part 120P and the connection circuit pattern part 120T can have a 10-point average surface roughness (Rz) in a range of 0.01 μm to 0.5 μm. Thereafter, in the embodiment, an insulating layer 111 can be formed under the metal layer CB2.

Next, referring to FIG. 15, the embodiment can perform a process of forming a through hole TH in the insulating layer 111. The through hole TH can be formed by laser processing, but is not limited thereto.

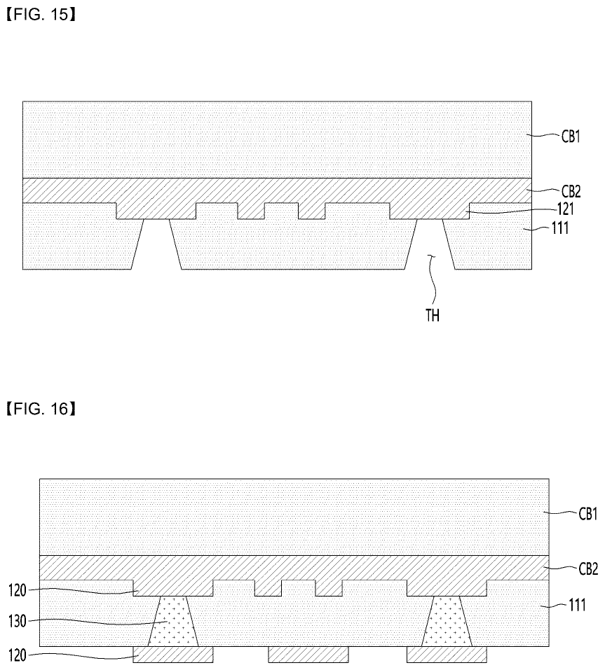

Next, referring to FIG. 16, the embodiment may perform a process of forming a wiring electrode 120 and a via electrode 130 on an insulating layer 111.

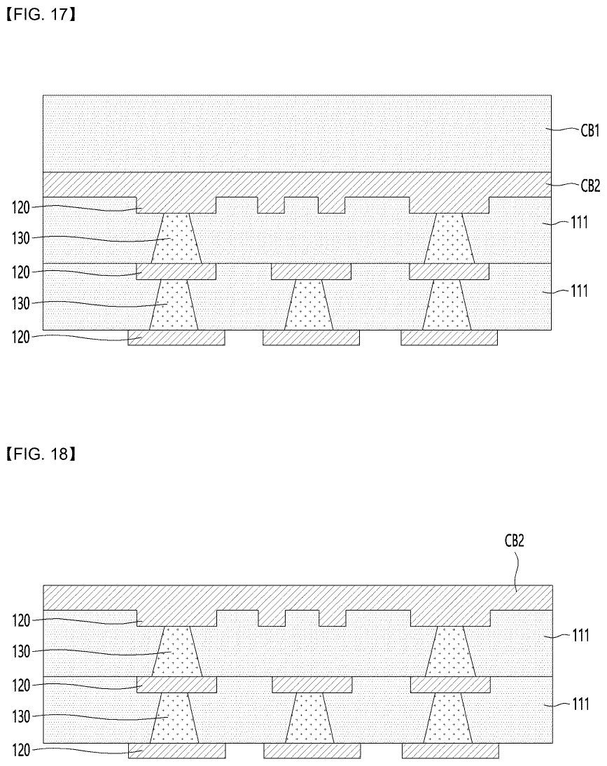

Next, referring to FIG. 17, the embodiment may perform a process of laminating an additional build-up layer under the insulating layer 111. For example, the embodiment may perform a process of laminating a second layer of the insulating layer 111 under a first layer of the insulating layer 111. Thereafter, the embodiment may perform a process of forming a wiring electrode 120 and a via electrode 130 on the second layer of the insulating layer 111 by repeating the processes of FIGS. 15 and 16.

Next, referring to FIG. 18, the embodiment may perform a process of removing a carrier board from a circuit board manufactured as described above. For example, the embodiment may perform a process of separating a carrier insulating layer CB1 and a metal layer CB2 from each other on the carrier board. Accordingly, in the circuit board of the embodiment, the metal layer CB2 included in the carrier board remains at an outermost side.

Next, referring to FIG. 19, the embodiment may proceed with a process of forming a conductive metal part 141 on the upper surface of the metal layer CB2. The conductive metal part 141 may be disposed in a region that vertically overlaps the wiring electrode 120 of the pad part 120P among the metal layers CB2 of the carrier board. At this time, the conductive metal part 141 may be formed of a metal material having selective etching properties with respect to the metal layer CB2 of the carrier board.

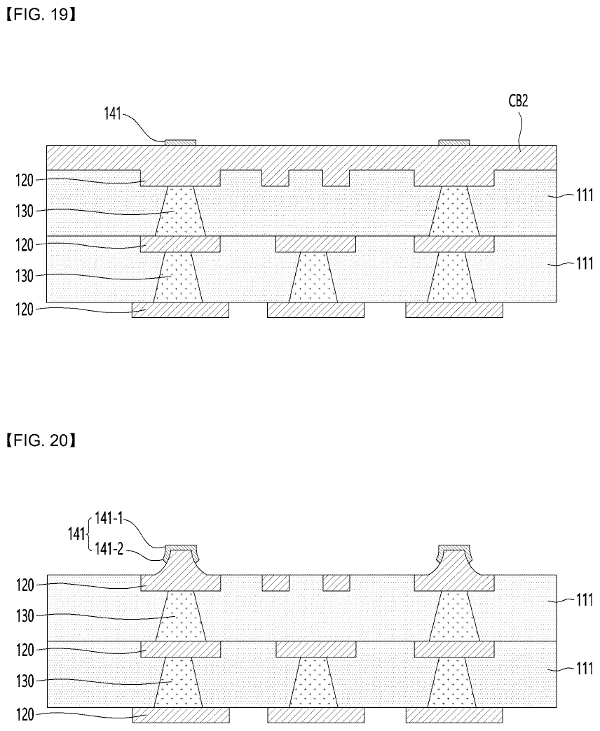

Next, referring to FIG. 20, the embodiment may proceed with a process of forming a second portion 122 of the pad part 120P by etching the metal layer CB2 of the carrier board using the conductive metal part 141. At this time, depending on the etching characteristics, the side surface of the second portion 122 may include a side surface having a curvature. In addition, the conductive metal part 141 may not vertically overlap at least a part of the upper surface of the second portion 122 by etching the second portion 122. That is, the conductive metal part 141 may include a contact portion 141-1 and an extension portion 141-2. The extension portion 141-2 may be in full contact with the side surface of the second portion 122 of the pad part 120P having a curvature according to the etching characteristics. However, the embodiment is not limited thereto, and the extension portion 141-2 may have a shape illustrated in any one of FIGS. 8 to 11.

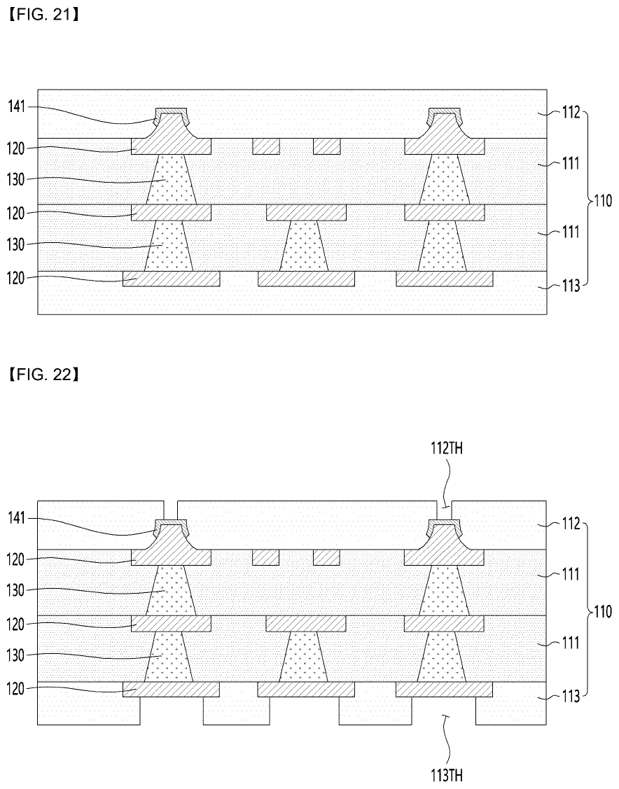

Next, referring to FIG. 21, the embodiment may perform a process of forming a first protective layer 112 and a second protective layer 113 on the upper surface and the lower surface of the insulating layer 111, respectively.

Next, referring to FIG. 22, the embodiment may perform a process of forming an opening 112TH vertically overlapping the contact portion 141-1 of the conductive metal part 141 in the first protective layer 112. In addition, the embodiment may perform a process of forming at least one opening 113TH in the second protective layer 113.

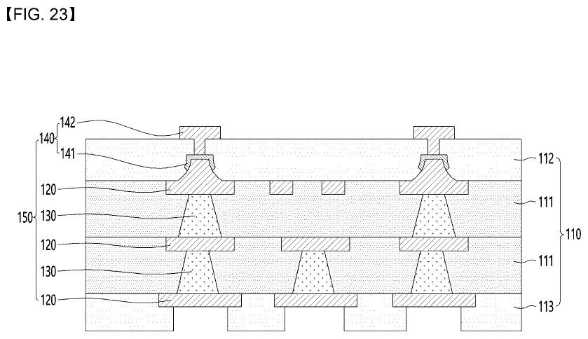

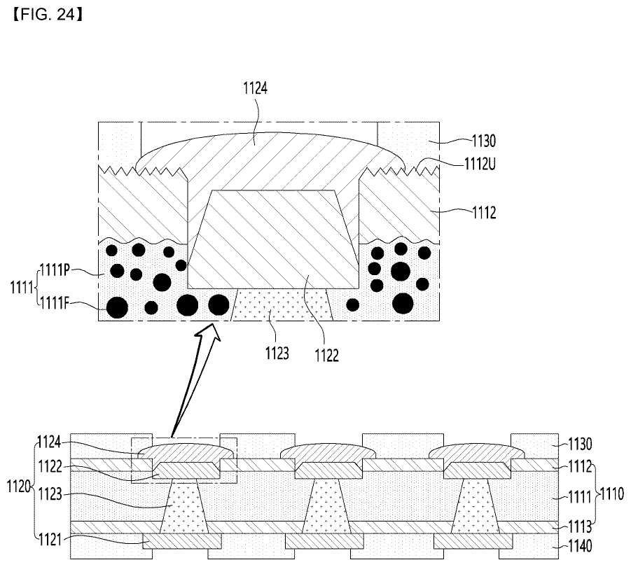

Next, referring to FIG. 23, the embodiment may perform a process of forming a coupling portion 142 in the opening 112TH of the first protective layer 112. At this time, the coupling portion 142 may include a through portion 142-1 filling the opening 112TH of the first protective layer 112 and a protruding portion 142-2 disposed on the first protective layer 112.

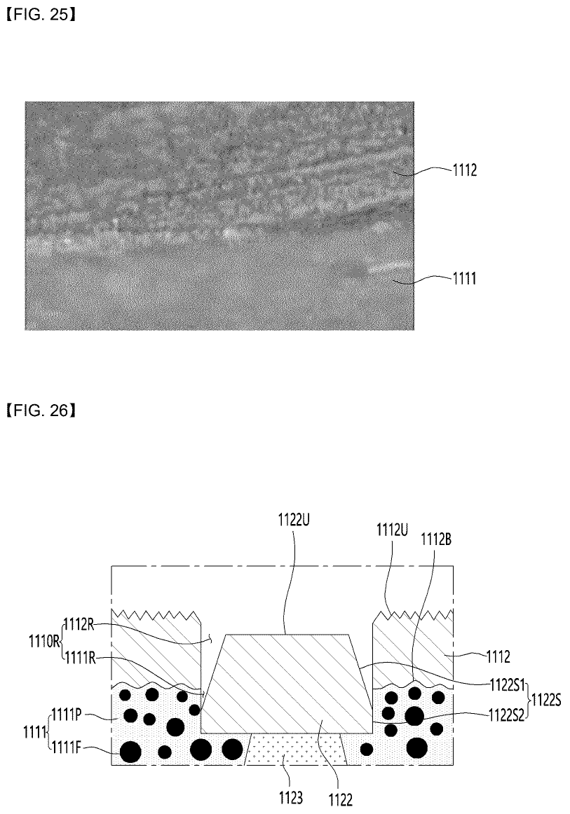

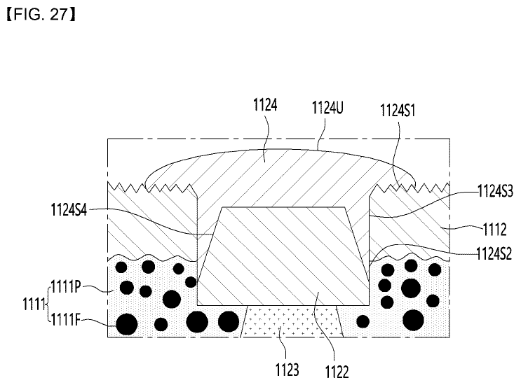

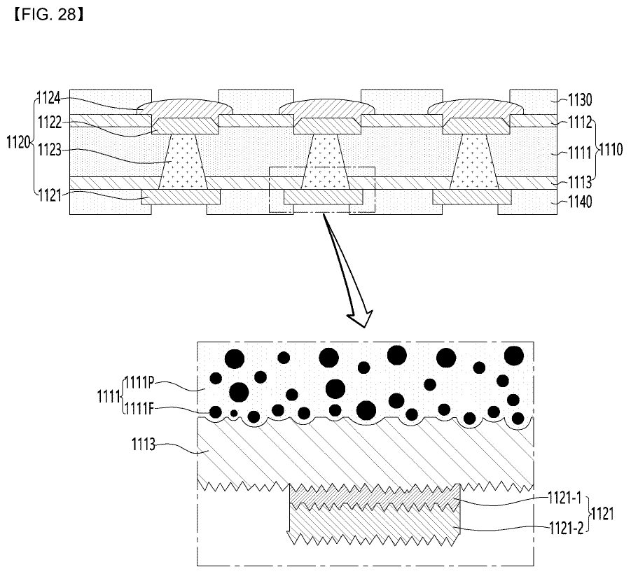

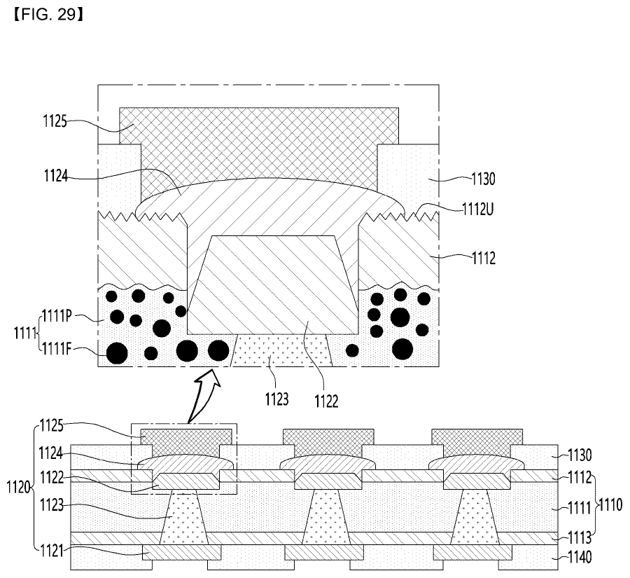

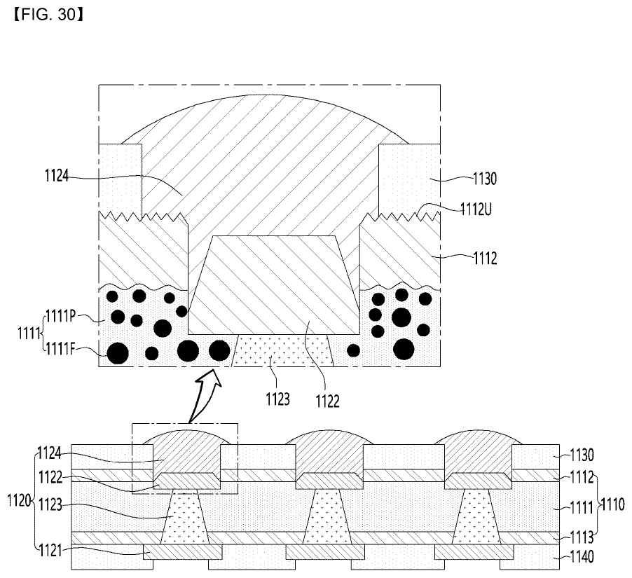

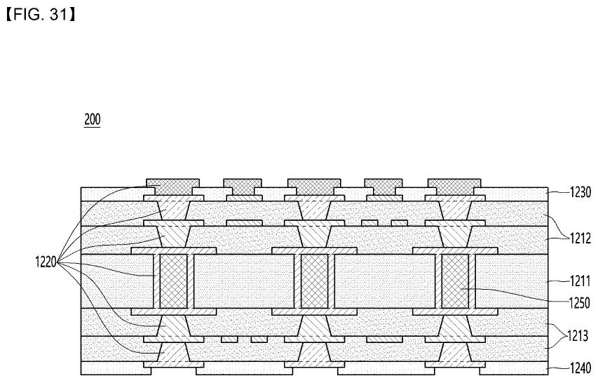

FIG. 24 is a cross-sectional view showing a circuit board according to a second embodiment, FIG. 25 is an optical microscope photograph showing an interface of an insulating layer provided in a circuit board according to the embodiment of FIG. 24, FIG. 26 is a cross-sectional view showing a state before arranging a conductive metal part in a region of FIG. 24, FIG. 27 is a drawing showing a state after arranging a conductive metal part in FIG. 26, FIG. 28 is a drawing showing a detailed layer structure of a lower wiring electrode in the circuit board of FIG. 24, FIG. 29 is a cross-sectional view showing a circuit board according to a third embodiment, FIG. 30 is a cross-sectional view showing a circuit board according to a fourth embodiment, and FIG. 31 is a cross-sectional view showing a circuit board according to a fifth embodiment.

Hereinafter, a circuit board according to an embodiment will be specifically described with reference to FIGS. 24 to 9.

Referring to FIG. 24, a circuit board 1000 may include an insulating layer 1110, an electrode part 1120, a first protective layer 1130, and a second protective layer 1140. The electrode part 1120 may include a first wiring electrode 1121, a second wiring electrode 1122, and a via electrode 1123. The first wiring electrode 1121 may mean an electrode disposed on a lower surface of one layer of an insulating layer, and the second wiring electrode 1122 may mean an electrode disposed on an upper surface of one layer of an insulating layer. In addition, the electrode part 1120 may include a conductive metal part 1124 disposed on the second wiring electrode 1122. The circuit board 1000 in FIG. 24 may represent a single insulating layer 1110 for convenience of explanation, and the insulating layer 1110 may have a plurality of laminated structures along the vertical direction. In this case, the first wiring electrode 1121 may mean an electrode disposed on a lower surface of a lowest insulating layer among the plurality of insulating layers, and the second wiring electrode 1122 may mean an electrode disposed on an upper surface of an uppermost insulating layer among the plurality of insulating layers.

The insulating layer 1110 may include a plurality of layers based on one via electrode 1123. For example, the insulating layer 1110 may include a first layer 1111 and a second layer 1112. The first layer 1111 and the second layer 1112 of the insulating layer 1110 may include different insulating materials. For example, the first layer 1111 of the insulating layer 1110 may include a reinforcing member. The reinforcing member may mean a filler. That is, the reinforcing member may mean an inorganic filler and may have a different meaning from a glass fiber material that may extend along the horizontal direction of the insulating layer 1110. The first layer 1111 of the insulating layer 1110 may include an organic material including a filler. As an example, the first layer 1111 of the insulating layer 1110 may use ABF (Ajinomoto Build-up Film) corresponding a product released by Ajinomoto Co., Ltd., or PID (Photo Imageable Dielectric resin). The second layer 1112 of the insulating layer 1110 may be disposed on the first layer 1111 of the insulating layer 1110. The second layer 1112 of the insulating layer 1110 may be disposed on the first layer 1111 while having a smaller thickness than the first layer 1111. For example, the second layer 1112 of the insulating layer 1110 may include an insulating material different from the insulating material provided in the first layer 1111. Preferably, the second layer 1112 of the insulating layer 1110 may not include a reinforcing member. For example, the second layer 1112 of the insulating layer 1110 may include a pure polymer.

For example, the insulating layer of the comparative example included only the first layer. In this case, when the insulating layer includes only the first layer, the physical reliability and electrical reliability of the circuit board may be deteriorated. Specifically, the first layer of the insulating layer may include a reinforcing member. In addition, when arranging the electrode part on the insulating layer, surface treatment may be performed to secure adhesion between the electrode part and the first layer of the insulating layer. The surface treatment may be etching the surface of the first layer of the insulating layer. At this time, when etching the surface of the first layer of the insulating layer, a filler provided in the first layer of the insulating layer may be exposed to an outside. In addition, the filler exposed to the outside may act as a factor that reduces the electrical reliability and physical reliability of the circuit board. For example, when chemical copper plating is performed on the first layer of the insulating layer to form a seed layer, the seed layer may be in contact with the resin of the first layer of the insulating layer and the filler of the first layer, respectively. In addition, the adhesion between the seed layer and the filler may be deteriorated depending on the characteristics of the seed layer. That is, when the contact area between the seed layer and the filler increases or the contact area between the seed layer and the resin decreases, the adhesion between the seed layer and the insulating layer may be reduced. In addition, a leakage current or an impedance of the circuit board may change due to changes in capacitance, resistance, inductance, etc., and thus the electrical reliability may also deteriorate. To solve this problem, a content of the filler provided in the insulating layer may be reduced. However, if the content of the filler is reduced, the rigidity of the circuit board may be reduced accordingly. In addition, if the rigidity of the circuit board is reduced, a reliability problem may occur in which the circuit board is greatly bent in a specific direction. In addition, if the electrode part is in contact with the filler, the transmission loss of the signal transmitted through the electrode part may increase due to the physical properties of the filler, and the electrical characteristics may deteriorate accordingly.

Therefore, the embodiment can improve the electrical characteristics of the electrode part 1120 while securing the adhesion between the insulating layer 1110 and the electrode part 1120, and for this purpose, the insulating layer 1110 can include a first layer 1111 and a second layer 1112 on the first layer 1111. The first layer 1111 of the insulating layer 1110 can be composed of an organic material including a reinforcing member. As an example, the reinforcing member can mean a filler. Through this, the first layer 1111 can secure the rigidity of the insulating layer 1110 while enabling the stable placement of the electrode part 1120 on the insulating layer 1110. The second layer 1112 of the insulating layer 1110 can be provided on the first layer 1111 of the insulating layer 1110. The second layer 1112 of the insulating layer 1110 may not include a reinforcing member. In addition, at least a part of the electrode part 1120 may be disposed on the second layer 1112 of the insulating layer 1110. For example, at least a part of the electrode part 1120 may be in contact with the second layer 1112 of the insulating layer 1110. At this time, the second layer 1112 of the insulating layer 1110 may not include a reinforcing member. Accordingly, the electrode part 1120 may not be in contact with the reinforcing member. Therefore, the embodiment can improve the adhesion between the electrode part 1120 and the insulating layer 1110. Furthermore, the embodiment can improve the electrical characteristics of the electrode part 1120.

A third layer 1113 may be provided under the first layer 1111 of the insulating layer 1110. The third layer 1113 may include a same material as the second layer 1112. The third layer 1113 may include an organic material that does not include a reinforcing member. The third layer 1113 may be a pure polymer that does not include a reinforcing member. At this time, the third layer 1113 of the insulating layer 1110 may include a same insulating material as the second layer 1112, and thus may also be referred to as a “second layer”. For example, when the circuit board has a plurality of laminated structures, one of the plurality of insulating layers may include the first layer 1111, the second layer 1112, and the third layer 1113 of the insulating layer 1110. For example, when the substrate has a plurality of laminated structures, one of the plurality of insulating layers may include the first layer 1111 and the second layer 1112 of the insulating layer 1110. For example, when the circuit board has a plurality of laminated structures, one of the plurality of insulating layers may include the first layer 1111 and the third layer 1113 of the insulating layer 1110.

The first layer 1111 of the insulating layer 1110 may have a thickness in a range of 20 μm to 40 μm. Preferably, the first layer 1111 of the insulating layer 1110 may satisfy a thickness in a range of 22 μm to 38 μm. More preferably, the first layer 1111 of the insulating layer 1110 may satisfy a thickness in a range of 25 μm to 35 μm. If the thickness of the first layer 1111 is less than 20 μm, the rigidity of the circuit board 1000 may be deteriorated. In addition, if the thickness of the first layer 1111 is less than 20 μm, the electrode part 1120 may not be stably disposed, and thus the electrical reliability of the circuit board may deteriorate. In addition, if the thickness of the first layer 1111 of the insulating layer 1110 exceeds 40 μm, the overall thickness of the circuit board 1000 may increase, and thus the thickness of the semiconductor package may increase. In addition, if the thickness of the first layer 1111 of the insulating layer 1110 exceeds 40 μm, it may be difficult to miniaturize the electrode part 1120 of the circuit board 1000.

The second layer 1112 of the insulating layer 1110 may have a thickness smaller than that of the first layer 1111. For example, the second layer 1112 of the insulating layer 1110 may have a thickness in a range of 1 μm to 5 μm. Preferably, the second layer 1112 of the insulating layer 1110 may have a thickness in the range of 1.2 μm to 4 μm. More preferably, the second layer 1112 of the insulating layer 1110 may satisfy a range of 1.5 μm to 3 μm. Preferably, the thickness of the second layer 1112 of the insulating layer 1110 may satisfy a range of 2% to 25% of the thickness of the first layer 1111 of the insulating layer 1110. Preferably, the thickness of the second layer 1112 of the insulating layer 1110 can satisfy a range of 3% to 18% of the thickness of the first layer 1111 of the insulating layer 1110. More preferably, the thickness of the second layer 1112 of the insulating layer 1110 can satisfy a range of 4% to 12% of the thickness of the first layer 1111 of the insulating layer 1110. If the thickness of the second layer 1112 of the insulating layer 1110 is less than 1 μm or less than 2% of the thickness of the first layer 1111, it may be difficult to provide a uniform centerline average surface roughness (Ra) to the upper surface of the second layer 1112 of the insulating layer 1110. If the thickness of the second layer 1112 of the insulating layer 1110 is less than 1 μm or less than 2% of the thickness of the first layer 1111, the filler provided in the first layer 1111 of the insulating layer 1110 may be exposed on the second layer 1112. As a result, the adhesion may be reduced or the electrical characteristics of the electrode part 1120 may be reduced due to the contact between the electrode part 1120 and the filler of the first layer 1111. In addition, if the thickness of the second layer 1112 of the insulating layer 1110 exceeds 5 μm or more than 25% of the thickness of the first layer 1111, the thickness of the insulating layer 1110 may increase, and thus the thickness of the circuit board may increase.

Here, the thickness may correspond to a distance of each layer of the insulating layer 1110 in the vertical direction of the circuit board. That is, the thickness may mean a length in a direction from the upper surface to the lower surface of the circuit board 1000, or from the lower surface to the upper surface, and may mean a length in the vertical direction of the circuit board. Here, the upper surface may mean a highest position along the vertical direction in each component, and the lower surface may mean a lowest position along the vertical direction in each component. In addition, these positions may be referred to as opposite to each other.

The first layer 1111 of the insulating layer 1110 is provided with a filler, and the second layer 1112 of the insulating layer 1110 is not provided with a filler, so that an interface between the first layer 1111 and the second layer 1112 can be distinguished. Specifically, a refractive index of the filler can be higher than that of general epoxy or acrylic resin. A difference in refractive index due to this can occur, and accordingly, the interface between the first layer 1111 including the filler and the second layer 1112 not including the filler can be distinguished. For example, as illustrated in FIG. 25, when an image is acquired by reflecting and refracting electrons, image colors of the first layer 1111 and the second layer 1112 of the insulating layer 1110 may appear differently, and thus, the interface may be distinguished.

The first layer 1111 of the insulating layer 1110 may be provided with a filler of a certain level or higher. For example, the first layer 1111 of the insulating layer 1110 may include a resin 1111P and a reinforcing member 1111F. The reinforcing member 1111F may mean a filler. The reinforcing member 1111F may be provided in the first layer 1111 in a certain amount or higher. The content of the reinforcing member 1111F in the first layer 1111 of the insulating layer 1110 can satisfy a range of 60 wt % to 85 wt %. If the content of the first layer 1111 of the insulating layer 1110 is less than 60 wt %, the rigidity of the insulating layer 1110 may be reduced. If the content of the reinforcing member 1111F in the first layer 1111 of the insulating layer 1110 exceeds 85 wt %, signal transmission characteristics of the via electrode 1123 penetrating the first layer 1111 may be reduced.

At this time, in a prior art, when a reinforcing member 1111F exceeding 60 wt % was disposed on the first layer 1111 of the insulating layer 1110, the reinforcing member 1111F was exposed to an upper or lower side of the insulating layer 1110, and thus the electrode part 1120 and the reinforcing member 1111F were in contact with each other.

In contrast, since the embodiment includes the second layer 1112 on the first layer 1111 as the insulating layer 1110, the problem of the electrode part 1120 and the filler being in contact with each other can be solved even if the filler content in the first layer 1111 is increased. Therefore, the embodiment can improve the rigidity of the circuit board 1000 and, accordingly, improve the electrical characteristics of the electrode part 1120.

A surface of the insulating layer 1110 may be provided with a predetermined level of centerline average surface roughness (Ra). For example, the insulating layer 1110 may include an interface 1112B between the first layer 1111 and the second layer 1112. In addition, the insulating layer 1110 may include an upper surface 1112U of the second layer 1112. A centerline average surface roughness (Ra) of the interface 1112B may be different from a centerline average surface roughness (Ra) of the upper surface 1112U. A deviation of the centerline average surface roughness (Ra) of a plurality of lines provided at the interface 1112B may be greater than a deviation of the centerline average surface roughness (Ra) of a plurality of lines provided at the upper surface 1112U.

That is, the embodiment can provide a centerline average surface roughness (Ra) that is uniform and devoid of deviation to the second layer 1112 of the insulating layer 1110. This may be because the surface roughness provided to the metal layer (not shown) with a certain level of surface roughness is transferred to the second layer 1112 of the insulating layer 1110 by attaching the metal layer to which the surface roughness is provided on the second layer 1112 of the insulating layer 1110. Through this, a uniform centerline average surface roughness (Ra) can be provided to the upper surface 1112U of the second layer 1112 of the insulating layer 1110. However, the interface 1112B between the first layer 1111 and the second layer 1112 of the insulating layer 1110 can be provided with the centerline average surface roughness (Ra) by the reinforcing member 1111F included in the first layer 1111. At this time, particle sizes of the reinforcing member 1111F provided in the first layer 1111 of the insulating layer 1110 may have different particle sizes. That is, fillers having various particle sizes may be disposed in the first layer 1111 of the insulating layer 1110. Accordingly, the centerline average surface roughness (Ra) of the interface 1112B between the first layer 1111 and the second layer 1112 of the insulating layer 1110 may have a deviation for each line.

The centerline average surface roughness (Ra) of the upper surface 1112U of the second layer 1112 can satisfy a range of 0.2 μm to 1.5 μm. Preferably, the centerline average surface roughness (Ra) of the upper surface 1112U of the second layer 1112 can satisfy a range of 0.25 μm to 1.3 μm. More preferably, the centerline average surface roughness (Ra) of the upper surface 1112U of the second layer 1112 can satisfy a range of 0.3 μm to 1.25 μm. If the centerline average surface roughness (Ra) of the upper surface 1112U of the second layer 1112 is less than 0.2 μm, adhesion between the electrode part 1120 and the upper surface 1112U of the second layer 1112 may not be secured, and thus a physical reliability problem in which the electrode part 1120 is peeled off from the insulating layer 1110 may occur. If the centerline average surface roughness (Ra) of the upper surface 1112U of the second layer 1112 exceeds 1.5 μm, transmission loss of a signal transmitting through the electrode part 1120 may increase. For example, as a frequency of the transmitting signal increases, a skin effect occurs in which the signal flows along the surface of the electrode part 1120. At this time, if the centerline average surface roughness (Ra) of the upper surface 1112U of the second layer 1112 exceeds 1.5 μm, a length of the surface may be lengthened, and a transmission distance of the signal flowing along the surface may also increase. In addition, if the signal transmission distance increases, the signal transmission loss due to this may increase. Accordingly, it may be difficult to smoothly operate the semiconductor device, and it may be difficult to smoothly operate the server or electronic product. That is, the centerline average surface roughness (Ra) of the upper surface 1112U of the second layer 1112 may be directly related to the reliability of the server or electronic product, and thus may have technical interoperability or functional integrity.

The centerline average surface roughness (Ra) of the upper surface 1112U of the second layer 1112 may be smaller than the particle size of the fillers of the reinforcing member 1111F provided in the first layer 1111. Preferably, the particle sizes of the fillers may have various sizes. At this time, the average value of the particle sizes of the fillers may be larger than the centerline average surface roughness (Ra) of the upper surface 1112U of the second layer 1112. Through this, the adhesion between the electrode part 1120 and the insulating layer 1110 disposed on the upper surface 1112U of the second layer 1112 may be secured, while the transmission loss of the signal flowing through the electrode part 1120 may be reduced to improve the signal characteristics.

The lower surface of the third layer 1113 of the insulating layer 1110 may have a centerline average surface roughness (Ra) corresponding to the centerline average surface roughness (Ra) of the upper surface 1112U of the second layer 1112.

Here, the centerline average surface roughness (Ra) may be expressed as a height of a concave-convex surface. For example, first concave-convex surfaces may be provided at the interface between the first layer 1111 and the second layer 1112 of the insulating layer 1110. In addition, second concave-convex surfaces may be provided at the upper surface of the second layer 1112 of the insulating layer 1110. In addition, heights of the first concave-convex surfaces and heights of the second concave-convex surfaces may be different. In addition, the deviation of the heights of the first concave-convex surfaces may be greater than the deviation of the heights of the second concave-convex surfaces. Preferably, the heights of the second concave-convex surfaces may be uniform.

Meanwhile, referring to FIG. 26, the insulating layer 1110 may include a recess 1110R in which at least a part of the electrode part 1120 is disposed. The recess 1110R may be provided concavely from the upper surface of the insulating layer 1110 toward the lower surface. The recess 1110R may be a space where the second wiring electrode 1122 of the electrode part 1120 is disposed.

The recess 1110R may be provided in the first layer 1111 and the second layer 1112 of the insulating layer 1110. At this time, the recess 1110R may penetrate the second layer 1112 of the insulating layer 1110 while not penetrating the first layer 1111. For example, the recess 1110R may include a first part 1111R provided in the first layer 1111 of the insulating layer 1110 and a second part 1112R provided in the second layer 1112 while being connected to the first part 1111R. The first part 1111R may be provided in a form of a groove that does not penetrate the first layer 1111 of the insulating layer 1110. The second part 1112R may be provided in a form of a through hole that penetrates the second layer 1112 of the insulating layer 1110.

The first wiring electrode 1121 and the second wiring electrode 1122 may have different vertical cross-sectional shapes. For example, the second wiring electrode 1122 may be provided at an uppermost side of the circuit board 1000 and may function as an electrode to which an interposer or a semiconductor device is connected. The second wiring electrode 1122 may mean the wiring electrode 120 in the circuit board described with reference to FIG. 2. A conductive metal part 1124 may be disposed on the second wiring electrode 1122. At this time, the conductive metal part 1124 of the second embodiment may be formed in a different method from the conductive metal part of the first embodiment, and thus may have a different structure from the conductive metal part of the first embodiment. At this time, in order to improve the bonding strength between the second wiring electrode 1122 and the conductive metal part 1124, a process of etching the conductive metal part 1124 may be performed. Accordingly, the recess 1110R of the insulating layer 1110 may include a portion filled with the second wiring electrode 1122 and a portion filled with the conductive metal part 1124.

The second wiring electrode 1122 may include a plurality of outer surfaces. The second wiring electrode 1122 may include an upper surface 1122U, a side surface 1122S, and a lower surface. The upper surface of the second wiring electrode 1122 and the lower surface of the second wiring electrode 1122 may have different widths. For example, the upper surface of the second wiring electrode 1122 may have a smaller width than the lower surface of the second wiring electrode 1122. This may be because a portion of the upper surface and side surface of the second wiring electrode 1122 is etched and removed during an etching process of the second wiring electrode 1122 to increase a contact area with the conductive metal part 1124. The upper surface 1122U of the second wiring electrode 1122 may not be in contact with the insulating layer 1110. The upper surface 1122U of the second wiring electrode 1122 may not be in contact with the first layer 1111 and the second layer 1112 of the insulating layer 1110. The upper surface 1122U of the second wiring electrode 1122 may be positioned lower than the upper surface of the insulating layer 1110. Preferably, the upper surface 1122U of the second wiring electrode 1122 may be positioned lower than the upper surface 1112U of the second layer 1112 of the insulating layer 1110. For example, the upper surface 1122U of the second wiring electrode 1122 may be positioned lower than an uppermost second concave-convex surface among the second concave-convex surfaces provided at the upper surface 1112U of the second layer 1112. The side surface 1122S of the second wiring electrode 1122 may include a plurality of inclinations.

The side surface 1122S of the second wiring electrode 1122 may include a first inclination 1122S1 adjacent to the upper surface 1122U of the second wiring electrode 1122 and increasing in width toward the lower surface of the second wiring electrode 1122. The side surface 1122S of the second wiring electrode 1122 may include a second inclination 1122S2 adjacent to a lower surface of the second wiring electrode 1122 and different from the first inclination 1122S1. The second inclination of the side surface 1122S of the second wiring electrode 1122 may be an inclination whose width changes toward a upper surface of the second wiring electrode 1122, but is not limited thereto. The second inclination 1122S2 of the side surface 1122S of the second wiring electrode 1122 may not horizontally overlap the second layer 1112 of the insulating layer 1110. The second inclination 1122S2 of the side surface 1122S of the second wiring electrode 1122 may be in contact with the first layer 1111. For example, the second inclination 1122S2 of the side surface 1122S of the second wiring electrode 1122 may be in contact with the inner wall of the first part 1111R of the recess 1110R provided in the first layer 1111.

The first inclination 1122S1 of the side surface 1122S of the second wiring electrode 1122 may include a first portion horizontally overlapping the first layer 1111 and a second portion horizontally overlapping the second layer 1112. The first inclination 1122S1 of the side surface 1122S of the second wiring electrode 1122 may not contact the insulating layer 1110. For example, the first inclination 1122S1 of the side surface 1122S of the second wiring electrode 1122 may be horizontally spaced apart from an inner wall of a first part 1111R of a recess 1110R provided in the first layer 1111 and an inner wall of a second part 1112R of a recess 1110R provided in the second layer 1112. The second wiring electrode 1122 may not entirely fill the recess 1110R but may only partially fill the recess. This is because the manufacturing process of the second wiring electrode 1122 includes a process of surface-treating the second wiring electrode 1122, and, a portion of the outer surface of the second wiring electrode 1122 may be removed by etching in the surface-treating process. Accordingly, the second wiring electrode 1122 may include a crevice spaced from the inner wall of the recess 1110R.

The conductive metal part 1124 is disposed on the second wiring electrode 1122. Preferably, the second wiring electrode 1122 has a pad part, and the conductive metal part 1124 is disposed on the pad part. The conductive metal part 1124 may include a different metal from the second wiring electrode 1122. The conductive metal part 1124 may include a metal material for improving the bonding strength between the second wiring electrode 1122 and the connecting member. In addition, the conductive metal part 1124 may include a metal material for improving the bonding strength between the second wiring electrode 1122 and the bonding part. For example, the conductive metal part 1124 may include nickel. In addition, when the conductive metal part 1124 includes nickel, the adhesion between the second wiring electrode 1122 and the bonding part may be increased. In addition, when electrical connection is formed with the second wiring electrode 1122 later using a material such as solder, the solder may diffuse into the second wiring electrode 1122 to form an inter-metallic compound, and the inter-metallic compound has a problem of poor mechanical and electrical reliability. In particular, if the second wiring electrode 1122 is made of copper, a problem of forming the inter-metallic compound may be further aggravated. However, if nickel is disposed, diffusion of solder can be prevented, thereby preventing the formation of the inter-metallic compound, thereby improving the electrical and mechanical reliability of the semiconductor package. The conductive metal part 1124 may include a metal other than nickel. For example, the conductive metal part 1124 may include gold. For example, the conductive metal part 1124 may include palladium.

The conductive metal part 1124 may protrude above the upper surface of the insulating layer 1110. For example, at least a portion of the conductive metal part 1124 may be provided in the recess 1110R of the insulating layer 1110, and the remaining portion may protrude above the insulating layer 1110. Therefore, when combining a semiconductor package and an electronic device through thermal compression (TC) bonding in the future, there is an advantage in that the TC bonding process can be smoothly performed by securing consistency and diffusion.

The conductive metal part 1124 may be provided to surround the second wiring electrode 1122 in the recess 1110R. For example, the first inclination 1122S1 of the upper surface 1122U and the side surface 1122S of the second wiring electrode 1122 may not be in contact with the insulating layer 1110. Accordingly, the conductive metal part 1124 may include a portion disposed in the recess 1110R, and the portion disposed in the recess 1110R may be provided to cover the first inclination 1122S1 of the upper surface 1122U and the side surface 1122S of the second wiring electrode 1122.

Specifically, referring to FIG. 27, the conductive metal part 1124 may include an embedded portion disposed in the recess 1110R. In addition, the embedded portion of the conductive metal part 1124 may include a portion that contacts the insulating layer 1110. The embedded portion of the conductive metal part 1124 may include a portion 1124S2 that contacts the inner wall of the first part 1111R of the recess 1110R, and a portion 1124S3 that contacts the inner wall of the second part 1112R of the recess 1110R.

In addition, the embedded portion of the conductive metal part 1124 may include a portion that contacts the second wiring electrode 1122. Specifically, the embedded portion of the conductive metal part 1124 may include a portion 124S4 that contacts the first inclination 1122S1 of the upper surface and side surface 112U of the second wiring electrode 1122.

In addition, the conductive metal part 1124 may include a protruded portion that protrudes above the insulating layer 1110. The protruded portion of the conductive metal part 1124 may include a portion that contacts the insulating layer 1110. Specifically, the protruded portion of the conductive metal part 1124 may include a portion 1124S1 that contacts the upper surface 1112U of the second layer 1112 of the insulating layer 1110. That is, the protruded portion of the conductive metal part 1124 may be provided to extend on the second wiring electrode 1122 in a horizontal direction. Accordingly, a part of the protruding portion of the conductive metal part 1124 may vertically overlap with the second wiring electrode 1122, and the remaining part may not vertically overlap with the second wiring electrode 1122. In addition, the lower surface 1124S1 of the part that does not vertically overlap with the second wiring electrode 1122 may contact the upper surface 1112U of the second layer 1112 of the insulating layer 1110.

The conductive metal part 1124 may include an upper surface 1124U protruding above the insulating layer 1110. The upper surface 1124U of the conductive metal part 1124 may include a convex portion extending away from the upper surface of the insulating layer 1110. At least a part of the conductive metal part 1124 is provided in the recess 1110R of the insulating layer 1110. Accordingly, the embodiment can increase a contact area between the conductive metal part 1124 and the second wiring electrode 1122. Through this, the embodiment can improve the adhesion between the conductive metal part 1124 and the second wiring electrode 1122. Accordingly, the embodiment can improve physical reliability between the conductive metal part 1124 and the second wiring electrode 1122. Furthermore, since the embodiment has a structure in which the conductive metal part 1124 surrounds the outer surface of the second wiring electrode 1122, the signal can be smoothly transmitted between the conductive metal part 1124 and the second wiring electrode 1122, and thus the electrical characteristics can be improved. In addition, the embodiment can allow the thickness of a plurality of conductive metal parts 1124 spaced apart in the horizontal direction to be uniform. Specifically, the conductive metal part 1124 can be disposed on the second layer of the insulating layer. At this time, the second layer of the insulating layer may be a pure resin layer that does not include a reinforcing member such as a filler. Accordingly, a uniform surface roughness may be imparted to the surface of the second layer. In addition, a plurality of conductive metal parts may be disposed on the second layer of the insulating layer to which the uniform surface roughness is imparted. Through this, the embodiment can enable the plurality of conductive metal parts to have a uniform thickness. In addition, when a bonding part is additionally disposed on the conductive metal part, the plurality of bonding parts can have a uniform thickness. Through this, the embodiment can enable the semiconductor device to be stably bonded to the conductive metal part or the bonding part. Therefore, the embodiment can enable the semiconductor device to operate stably and smoothly, and thereby improve the operating characteristics of a server or an electronic product.

Referring to FIG. 28, the first wiring electrode 1121 and the second wiring electrode 1122 may have different layer structures. The second wiring electrode 1122 may have a layer structure that does not include a seed layer. Differently, the first wiring electrode 1121 may have a multiple layer structure including a seed layer.

For example, the first wiring electrode 1121 may include a first metal layer 1121-1 disposed under a third layer 1113 of an insulating layer 1110. The first metal layer 1121-1 may be an electroless plating layer. The first metal layer 1121-1 may be a chemical copper plating layer. In addition, the first wiring electrode 1121 may include a second metal layer 1121-2 disposed under the first metal layer 1121-1. The second metal layer 1121-2 may be an electrolytically plated layer using the first metal layer 1121-1 as a seed layer. At this time, a predetermined level of centerline average surface roughness (Ra) may be provided to the lower surface of the third layer 1113 in contact with the first metal layer 1121-1. Accordingly, the embodiment can improve the adhesion between the first metal layer 1121-1 of the first wiring electrode 1121 and the insulating layer 1110. At this time, the first metal layer 1121-1 of the embodiment does not contact the first layer 1111 of the insulating layer 1110. That is, the first metal layer 1121-1 does not contact the reinforcing member 1111F provided in the first layer 1111 of the insulating layer 1110. Through this, the embodiment can solve a problem of the adhesion between the first metal layer 1121-1 and the insulating layer 1110 being reduced by the reinforcing member 1111F. Furthermore, the embodiment can prevent the transmission loss of the signal flowing through the first metal layer 1121-1 from increasing by the reinforcing member 1111F. Through this, the embodiment can improve the physical reliability and electrical reliability of the circuit board. Accordingly, the operation of the semiconductor device can be performed smoothly, and further, the operation of the server or electronic product can be performed smoothly.

In addition, when the conductive metal part 1124 is included in the electrode part 1120, a width of the conductive metal part 1124 can have a range of 40 μm to 70 μm. If the width of the conductive metal part 1124 is smaller than 40 μm, the conductive metal part 1124 may collapse during thermal compression bonding because the width is too small. In addition, if the width of the conductive metal part 1124 is larger than 70 μm, it may have a problem in that it is difficult to correspond to a fine pitch of terminals of the semiconductor device or the electrode of the interposer.

Referring to FIG. 29, the electrode part 1120 may further include a bonding part 1125.

The bonding part 1125 may protrude on the conductive metal part 1124 in a direction away from the circuit board 1000. At this time, the embodiment illustrates that the bonding part 1125 is disposed on an upper side of the circuit board 1000, but is not limited thereto. For example, the bonding part 1125 may also be disposed on a lower side of the circuit board 1000. At this time, the bonding part 1125 may protrude above an upper surface of the first protective layer 1130. In addition, the conductive metal part 1124 may be positioned lower than the upper surface of the first protective layer 1130. The bonding part 1125 may be used to provide ease in a micro bonding process.

Referring to FIG. 30, the electrode part 1120 of the circuit board of the embodiment may include a conductive metal part 1124 having a structure that protrudes above the upper surface of the first protective layer 1130. For example, the upper surface of the conductive metal part 1124 of the second embodiment may be positioned lower than the upper surface of the first protective layer 1130. In addition, the upper surface of the conductive metal part 1124 of the third embodiment may be positioned lower than the upper surface of the first protective layer 1130, while the bonding part 1125 may be disposed on the conductive metal part 1124.

Unlike this, the conductive metal part 1124 of the fourth embodiment may be provided while filling a portion of the recess 1110R and filling the opening of the first protective layer 1130. Through this, the conductive metal part 1124 may have a structure protruding above the upper surface of the first protective layer 1130.

Referring to FIG. 31, the circuit board of the embodiment may be a core board.

For example, the insulating layer of the circuit board may include a first insulating layer 1211 of a core layer. The first insulating layer 1211 may be provided with a reinforcing member such as glass fiber. The insulating layer may include a second insulating layer 1212 provided on the first insulating layer 1211 and a third insulating layer 1213 provided under the first insulating layer 1211. The second insulating layer 1212 may have a structure in which a plurality of layers are laminated along a vertical direction. For example, the second insulating layer 1212 may be built up with a plurality of layers on the first insulating layer 1211, and each of build-up layers may include the first layer 1111 and the second layer 1112 of the insulating layer 1110 described in FIG. 24. In addition, the third insulating layer 1213 may also have a structure corresponding to the second insulating layer 1212. The electrode part 1220 may be disposed in the insulating layer. At this time, the electrode part 1220 may be disposed in the second insulating layer 1212 and the third insulating layer 1213.

Each of the second insulating layer 1212 and the third insulating layer 1213 includes a first layer including a reinforcing member and a second layer not including a reinforcing member as described above, thereby ensuring adhesion to the electrode part 1220 while improving the electrical characteristics of the electrode part 1220.

On the other hand, when the circuit board having the above-described characteristics of the invention is used in an IT device or home appliance such as a smart phone, a server computer, a TV, and the like, functions such as signal transmission or power supply can be stably performed. For example, if a circuit board having the features of the present invention performs a semiconductor package function, the circuit board can function to safely protect the semiconductor device from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor device. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1.-10. (canceled)

11. A circuit board comprising:
a build-up insulating part including a reinforcing member;
a pad part disposed on the build-up insulating part;
a conductive metal part disposed on the pad part;
a protective layer disposed on the conductive metal part; and
a bonding part passing through at least a part of the protective layer and electrically connected to the conductive metal part,
wherein the pad part includes a first portion inclined to widen a width in a horizontal direction along a vertical direction from an upper surface of the pad part toward a lower surface of the build-up insulating part, and a second portion extending from the first portion and having an inclination different from an inclination of the first portion, and
wherein at least a part of a side surface of the first portion of the pad part does not overlap the reinforcing member along the horizontal direction.

12. The circuit board of claim 11, wherein the bonding part includes a protruding portion disposed on the protective layer, and a through portion extended from the protruding portion and passing through at least a part of the protective layer and electrically connected to the conductive metal part.

13. The circuit board of claim 11, wherein the conductive metal part is disposed to cover at least a part of a side surface of the first portion.

14. The circuit board of claim 11, wherein a recess is provided at an upper surface of the build-up insulating part, and
wherein the second portion of the pad part is disposed in the recess.

15. The circuit board of claim 11, wherein the conductive metal part includes a metal material different from a metal material of at least one of the pad part and the bonding part.

16. The circuit board of claim 12, wherein the side surface of the first portion of the pad part has a curved surface.

17. The circuit board of claim 12, wherein the through portion does not overlap with the curved surface in the vertical direction.

18. The circuit board of claim 17, wherein a width of the protruding portion in the horizontal direction is smaller than a width of the second portion of the pad part.

19. The circuit board of claim 17, wherein the conductive metal part includes a contact portion in contact with an upper surface of the first portion of the pad part, and an extension portion extending from the contact portion and not overlapping the upper surface of the first portion along the vertical direction.

20. The circuit board of claim 19, wherein the extension portion overlaps the curved surface along a vertical direction.

21. The circuit board of claim 19, wherein the extension portion is bent toward the upper surface of the build-up insulating part from the contact portion and overlaps the side surface of the first portion of the pad part in the horizontal direction.

22. The circuit board of claim 19, wherein the extension portion includes an upper surface, an inner surface facing the side surface of the first portion of the pad part, an outer surface opposite the inner surface, and a lower surface between the inner surface and the outer surface, and
wherein the upper surface and the outer surface of the extension portion are in contact with the protective layer.

23. The circuit board of claim 22, wherein the lower surface of the extension portion does not contact the side surface of the first portion of the pad part, and is in contact with the protective layer.

24. The circuit board of claim 22, wherein the inner surface of the extension portion includes a first region in contact with the side surface of the first portion of the pad part, and a second region in contact with the protective layer.

25. The circuit board of claim 19, wherein the lower surface of the extension portion is in contact with the side surface of the first portion of the pad part.

26. The circuit board of claim 11, further comprising:
a connection circuit pattern part embedded in an upper surface of the build-up insulating part,
wherein the connection circuit pattern part overlaps the second portion of the pad part in the horizontal direction and does not overlap the first portion of the pad part in the vertical direction and the horizontal direction.

27. The circuit board of claim 14, wherein the build-up insulating part includes an upper insulating layer disposed closest to the protective layer,
wherein the upper insulating layer includes a first layer including the reinforcing member; and a second layer disposed on the first layer and not including a reinforcing member, and
wherein at least a part of the first portion of the pad part overlaps the second layer along the horizontal direction.

28. The circuit board of claim 14, wherein the conductive metal part includes a first region disposed on the pad part, and a second region extending from the first region and extending between the side surface of the first portion of the pad part and an inner wall of the recess.

29. The circuit board of claim 27, wherein the recess includes a first part provided in the first layer of the upper insulating layer, and a second part provided in the second layer of the upper insulating layer and connected to the first part,
wherein at least a part of the second portion of the pad part is disposed in the first part of the recess, and
wherein at least a part of the first portion of the pad part is disposed in the second part of the recess.

30. The circuit board of claim 14, wherein a side surface of the first portion of the pad part overlaps an inner wall of the recess in the horizontal direction and is spaced apart from the inner wall of the recess, and
wherein a side surface of the second portion of the pad part is in contact with the inner wall of the recess.
